(19) United States
(12) Patent Application Publication
(10) Pub. No.: US 2018/0163318 A1
(43) Pub. Date: Jun. 14, 2018

(54) LAMINATED FILM

(71) Applicant: FUJIFILM Corporation, Tokyo (JP)

(72) Inventors: Makoto KAMO, Kanagawa (JP); Tatsuya OBA, Kanagawa (JP); Masayuki KUSUMOTO, Kanagawa (JP)

(73) Assignee: FUJIFILM Corporation, Tokyo (JP)

(21) Appl. No.: 15/892,646

(22) Filed: Feb. 9, 2018

Related U.S. Application Data
(63) Continuation of application No. PCT/JP2016/072793, filed on Aug. 3, 2016.

(30) Foreign Application Priority Data
Aug. 12, 2015 (JP) 2015-159658

(51) Int. Cl. C25D 5/56; C23C 14/20; C23C 14/34; C25D 3/38

(52) U.S. Cl. CPC C25D 5/56; C25D 3/38; C23C 14/34; C23C 14/205

(57) ABSTRACT

Provided is a laminated film which is capable of preventing quantum dots from being deteriorated due to moisture or oxygen and therefore has high durability, and is capable of narrowing the frame and therefore has high productivity. More specifically, provided is a laminated film, including a functional layer laminate having an optical functional layer and a gas barrier layer laminated on at least one main surface of the optical functional layer, and an edge face sealing layer formed so as to cover at least a part of an edge face of the functional layer laminate, in which a surface roughness Ra of the edge face of the functional layer laminate in a formation region of the edge face sealing layer is 0.1 to 2 μm and a thickness of the edge face sealing layer is 1 to 5 μm.

### CROSS-REFERENCE TO RELATED APPLICATIONS

This application is a Continuation of PCT International Application No. PCT/JP2016/072793 filed on Aug. 3, 2016, which claims priority under 35 U.S.C. § 119(a) to Japanese Patent Application No. 2015-159658 filed on Aug. 12, 2015. The above application is hereby expressly incorporated by reference, in its entirety, into the present application.

### BACKGROUND OF THE INVENTION

### 1. Field of the Invention

The present invention relates to a laminated film for use in a backlight of a liquid crystal display, or the like.

### 2. Description of the Related Art

Applications of a liquid crystal display (hereinafter, also referred to as an “LCD”) as a space-saving image display with low power consumption have been widespread year by year. Further, in recent liquid crystal displays, further power saving, an enhancement in color reproducibility, or the like is required as an improvement in LCD performance.

Along with power saving of LCD backlight, in order to increase the light utilization efficiency and improve the color reproducibility, using a quantum dot that converts a wavelength of incident light and emits the wavelength-converted light has been proposed.

The quantum dot is a crystal in the state of an electron whose movement direction is restricted in all directions three-dimensionally. In the case where nanoparticles of a semiconductor are three-dimensionally surrounded by a high potential barrier, the nanoparticles become quantum dots. The quantum dot expresses various quantum effects. For example, a “quantum size effect” is expressed in which a density of electronic states (energy level) is discretized. According to this quantum size effect, the absorption wavelength and luminescence wavelength of light can be controlled by changing the size of a quantum dot.

Generally, such quantum dots are dispersed in a resin or the like, and used as a quantum dot film for wavelength conversion, for example, by being disposed between a backlight and a liquid crystal panel.

In the case where excitation light is incident from a backlight to a film containing quantum dots, the quantum dots are excited to emit fluorescence. Here, white light can be realized by using quantum dots having different luminescence properties to emit light having a narrow half width of red light, green light, and blue light. Since the fluorescence by the quantum dot has a narrow half width, wavelengths can be properly selected to thereby allow the resulting white light to be designed so that the white light has high luminance and excellent color reproducibility.

Meanwhile, there are problems that quantum dots are susceptible to deterioration due to moisture or oxygen, and the luminescence intensity thereof decreases due to a photooxidation reaction. Therefore, gas barrier films have been laminated on both surfaces of a resin layer containing quantum dots to thereby protect the resin layer containing quantum dots. Hereinafter, the resin layer containing quantum dots is also referred to as a “quantum dot layer”.

However, merely protecting both main surfaces of the quantum dot layer with gas barrier films has a problem in which moisture or oxygen infiltrates from the edge face not protected by the gas barrier film, and therefore the quantum dots deteriorate.

Therefore, protecting the quantum dot layer, including the entire edge face (peripheral edge face) of the quantum dot layer, with a gas barrier film has been proposed.

For example, WO2012/102107A discloses a composition in which quantum dots (quantum dot phosphors) are dispersed in a cycloolefin (co)polymer in a concentration range of 0.01% to 20% by mass, and discloses a configuration having a gas barrier layer covering the entire surface of the resin molded body in which quantum dots are dispersed. Further, it is disclosed that such a gas barrier layer is a gas barrier film in which a silica film or an alumina film is formed on at least one surface of a resin layer.

JP2013-544018A discloses a display backlight unit having a remote phosphor film containing a quantum dot (QD) group, and discloses a configuration in which a QD phosphor material is sandwiched between two gas barrier films and a protective layer (inactive region) having gas barrier properties is provided in a region sandwiched between two gas barrier films around the QD phosphor material.

JP2009-283441A discloses a light emitting device including a color converting layer for converting at least a part of color light emitted from a light source portion into another color light and a water impermeable sealing sheet for sealing the color converting layer, and discloses a configuration having a protective layer (second bonding layer) provided in a frame shape along the outer circumference of the phosphor layer, that is, so as to surround the planar shape of the phosphor layer, in which the protective layer is formed of an adhesive material having gas barrier properties.

JP2010-061098A discloses a quantum dot wavelength converting structure including a wavelength converting portion containing quantum dots for wavelength-converting excitation light to generate wavelength-converted light and a dispersion medium for dispersing quantum dots, and a sealing member for sealing the wavelength converting portion, and discloses that the edge region of the sealing sheet is heated to be thermally adhered so that the wavelength converting portion is sealed.

### SUMMARY OF THE INVENTION

Meanwhile, the film including a quantum dot layer, which is used for LCDs, is a thin film of about 50 to 350 μm.

There has been a problem that it is very difficult to cover the entire surface of the thin quantum dot layer with a gas barrier film, thereby leading to poor productivity. In the case where the gas barrier film is folded so as to cover the entire surface of the quantum dot layer, there have also been problems in that the gas barrier layer is broken at the bent portion, and therefore the gas barrier properties are deteriorated.

On the other hand, in the case of a configuration in which a protective layer with gas barrier properties is formed so as to surround a quantum dot layer sandwiched between two gas barrier films, it is contemplated to form a protective layer and a resin layer by, for example, a so-called dam fill method. In other words, it is contemplated to produce a film in which a protective layer is formed on the peripheral edge portion of one gas barrier film, a quantum dot layer is formed in a region surrounded by the protective layer, and then the other gas barrier film is laminated on the protective layer and the quantum dot layer such that the quantum dot layer is sandwiched between the gas barrier films, and the edge face of the quantum dot layer is surrounded by the protective layer.

However, since the material of the protective layer that can be formed by such a method is an adhesive material or the like, high barrier properties cannot be imparted, and therefore gas barrier properties and durability are not sufficient.

Further, with such a dam fill method, there is a problem of having poor productivity because all the processes are batch-wise.

Further, in the configuration in which the opening of the edge portion of the two gas barrier films with the quantum dot layer sandwiched therebetween is narrowed or sealed, there has been a problem that the thickness of the quantum dot layer becomes thinner at the edge portion, so that the quantum dot layer cannot fully exhibit the function at the edge portion, the size of the effective usable area becomes smaller, and the frame portion becomes larger. In addition, since a gas barrier layer having high gas barrier properties is generally hard and brittle, in the case where a gas barrier film having such a gas barrier layer is suddenly bent, there has been a problem that the gas barrier layer is broken and the gas barrier properties are deteriorated.

The present invention has been made to solve the above-described problems of the related art, and it is an object of the present invention to provide a laminated film which is capable of preventing an optical functional layer such as a quantum dot layer from being deteriorated due to moisture or oxygen, has high durability, and is capable of narrowing the frame.

In order to achieve such an object, provided herein is a laminated film comprising:

a functional layer laminate having an optical functional layer and a gas barrier layer laminated on at least one main surface of the optical functional layer; and

an edge face sealing layer formed so as to cover at least a part of an edge face of the functional layer laminate,

in which a surface roughness Ra of the edge face of the functional layer laminate in a formation region of the edge face sealing layer is 0.1 to 2 μm and a thickness of the edge face sealing layer is 1 to 5 μm.

In such a laminated film of the present invention, it is preferred that the edge face sealing layer is formed so as to cover the entire edge face of the functional layer laminate.

Further, it is preferred that the edge face sealing layer has at least one layer selected from the group consisting of a resin layer, a metal layer, a metal oxide layer, a metal nitride layer, a metal carbide layer, and a metal carbonitride layer.

Further, it is preferred that the edge face sealing layer has a laminated structure in which a plurality of layers are laminated.

Further, it is preferred that the edge face sealing layer has a plurality of metal layers.

Further, it is preferred that the edge face sealing layer has a metal plating layer and a metal layer provided between the metal plating layer and the edge face of the functional layer laminate.

Further, it is preferred that a plurality of metal layers are provided between the metal plating layer and the edge face of the functional layer laminate.

Further, it is preferred that the edge face sealing layer has at least one inorganic compound layer selected from the group consisting of a metal oxide layer, a metal nitride layer, a metal carbide layer, and a metal carbonitride layer, and a resin layer provided between the inorganic compound layer and the edge face of the functional layer laminate.

According to the present invention as described above, it is possible to provide a laminated film which is capable of preventing quantum dots from being deteriorated due to moisture or oxygen, has high durability, and is capable of narrowing the frame.

### BRIEF DESCRIPTION OF THE DRAWINGS

FIG. 1 is a cross-sectional view conceptually showing an example of a laminated film of the present invention.

FIG. 2 is a cross-sectional view conceptually showing an example of a gas barrier film for use in a laminated film.

FIG. 3 is a cross-sectional view conceptually showing another example of the laminated film of the present invention.

FIG. 4 is a cross-sectional view conceptually showing a still another example of the laminated film of the present invention.

FIG. 5A is a schematic view for explaining an example of a production method for producing a laminated film of the present invention.

FIG. 5B is a schematic view for explaining an example of a production method for producing a laminated film of the present invention.

FIG. 5C is a schematic view for explaining an example of a production method for producing a laminated film of the present invention.

FIG. 5D is a schematic view for explaining an example of a production method for producing a laminated film of the present invention.

### DESCRIPTION OF THE PREFERRED EMBODIMENTS

Hereinafter, the laminated film of the present invention will be described in detail with reference to suitable embodiments shown in the accompanying drawings.

Descriptions of the constituent elements described below are sometimes made based on representative embodiments of the present invention, but the present invention is not limited to such embodiments.

In the present specification, the numerical range expressed by using “to” means a range including numerical values described before and after “to” as a lower limit value and an upper limit value, respectively.

Further, in the present specification, the term “(meth)acrylate” is to be used in at least one of acrylate or methacrylate, or shall be used in several meanings. The same applies to “(meth)acryloyl” and the like.

The laminated film of the present invention is a laminated film including a functional layer laminate having an optical functional layer and a gas barrier layer laminated on at least one main surface (maximum surface) of the optical functional layer, and an edge face sealing layer formed so as to cover at least a part of the edge face of the functional layer laminate, in which the surface roughness Ra of the edge face of the functional layer laminate in the formation region of the edge face sealing layer is 0.1 to 2 μm and the thickness of the edge face sealing layer is 1 to 5 μm.

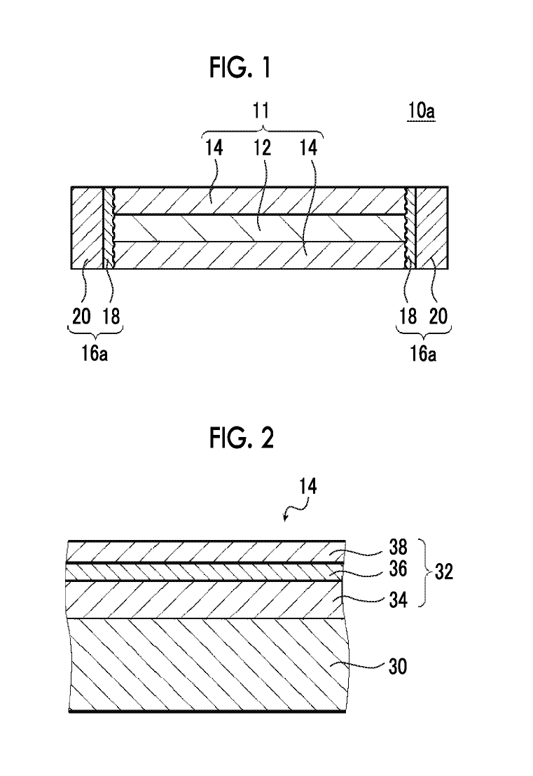

FIG. 1 is a cross-sectional view conceptually showing an example of a laminated film of the present invention.

A laminated film 10a shown in FIG. 1 includes a functional layer laminate 11 having an optical functional layer 12 and two gas barrier layers 14 each being laminated on both main surfaces of the optical functional layer 12, and an edge face sealing layer 16a formed so as to cover the entire edge face of the functional layer laminate 11.

In the laminated film 10a shown in FIG. 1, the functional layer laminate 11 has a rectangular planar shape as an example. The planar shape is a shape as seen from above in FIG. 1 and is the shape of the main surface of the laminate. That is, the laminated film 10a has a configuration in which the entire edge face of the four sides of the rectangular functional layer laminate 11 is covered and sealed with the edge face sealing layer 16a.

The optical functional layer 12 is a layer for exhibiting desired optical functions such as wavelength conversion.

As the optical functional layer 12, various layers capable of exhibiting an optical function can be used. Specific examples of the optical functional layer 12 include a fluorescent layer (wavelength conversion layer), an organic electroluminescence layer (organic EL layer), a photoelectric conversion layer for use in solar cells or the like, and an image display layer such as electronic paper.

In the laminated film 10a of the illustrated example, as a preferred embodiment, the optical functional layer 12 is a fluorescent layer which is formed by dispersing a large number of phosphors in a matrix such as a curable resin, and has a function of converting the wavelength of the light incident on the optical functional layer 12 and emitting the wavelength-converted light.

For example, in the case where blue light emitted from a backlight (not shown) is incident on the optical functional layer 12, the optical functional layer 12 wavelength-converts at least a part of the blue light into red light or green light and emits the wavelength-converted light, due to the effect of the phosphors contained therein.

Here, the blue light is a light having a luminescence center wavelength in a wavelength range of 400 to 500 nm, the green light is a light having a luminescence center wavelength in a wavelength range of more than 500 nm and 600 nm or less, and the red light is a light having a luminescence center wavelength in a wavelength range of more than 600 nm and 680 nm or less.

The function of wavelength conversion that the fluorescent layer exhibits is not limited to a configuration for wavelength-converting blue light into red light or green light, as long as it converts at least a part of incident light into light of a different wavelength.

The phosphor is excited by at least incident excitation light and emits fluorescence.

The type of the phosphor contained in the fluorescent layer is not particularly limited, and various known phosphors may be appropriately selected depending on the required performance of wavelength conversion or the like.

Examples of such phosphors include organic fluorescent dyes and organic fluorescent pigments, as well as phosphors in which phosphates, aluminates, metal oxides, or the like are doped with rare earth ions, phosphors in which semiconductive substances such as metal sulfides and metal nitrides are doped with activating ions, and phosphors utilizing a quantum confinement effect known as quantum dots. Among these, quantum dots capable of realizing a light source having a narrow luminescence spectrum width and excellent color reproducibility in the case of being used for a display, and having an excellent luminescence quantum efficiency are suitably used in the present invention.

That is to say, in the present invention, a quantum dot layer in which quantum dots are dispersed in a matrix such as a resin is suitably used as the optical functional layer 12. In the example shown in FIG. 1 or the like, as a preferred embodiment, the optical functional layer 12 is a quantum dot layer.

With respect to quantum dots, for example, reference can be made to paragraphs [0060] to [0066] of JP2012-169271A, but the quantum dots are not limited to those described therein. For the quantum dots, commercially available products can be used without any limitation. The luminescence wavelength of the quantum dot can be adjusted generally by the composition and size of the particles.

The quantum dots are preferably uniformly dispersed in the matrix but may be dispersed with bias in the matrix. The quantum dots may be used alone or in combination of two or more thereof.

In the case where two or more species of quantum dots are used in combination, two or more species of quantum dots with different wavelengths of emitted light may be used.

Specifically, known quantum dots include a quantum dot (A) having a luminescence center wavelength in a wavelength range in the range of more than 600 nm to 680 nm or less, a quantum dot (B) having a luminescence center wavelength in a wavelength range in the range of more than 500 nm to 600 nm or less, and a quantum dot (C) having a luminescence center wavelength in a wavelength range in the range of 400 nm to 500 nm. The quantum dot (A) is excited by excitation light to emit red light, the quantum dot (B) is excited by excitation light to emit green light, and the quantum dot (C) is excited by excitation light to emit blue light.

For example, in the case where blue light is incident as excitation light to a quantum dot layer containing the quantum dot (A) and the quantum dot (B), red light emitted from the quantum dot (A), green light emitted from the quantum dot (B) and blue light transmitting through the quantum dot layer can realize white light. Alternatively, ultraviolet light can be incident as excitation light to a quantum dot layer containing the quantum dots (A), (B), and (C), thereby allowing red light emitted from the quantum dot (A), green light emitted from the quantum dot (B), and blue light emitted from the quantum dot (C) to realize white light.

As the quantum dots, so-called quantum rods having a rod shape and emitting polarized light with directionality, or tetrapod type quantum dots may be used.

As described above, in the laminated film 10a of the present invention, the optical functional layer 12 is formed by dispersing quantum dots and the like using a resin or the like as a matrix.

Here, various known matrices for use in the quantum dot layer can be used for the matrix, but it is preferred that the matrix is obtained by curing a polymerizable composition (coating composition) containing at least two or more polymerizable compounds. The polymerizable groups of the polymerizable compounds to be used in combination of at least two or more thereof may be the same or different, and preferably at least two of these compounds have at least one or more common polymerizable groups.

The type of the polymerizable group is not particularly limited, but it is preferably a (meth)acrylate group, a vinyl group, an epoxy group, or an oxetanyl group, more preferably a (meth)acrylate group, and still more preferably an acrylate group.

It is preferred that the polymerizable compound to be the matrix of the optical functional layer 12 includes at least one first polymerizable compound consisting of a monofunctional polymerizable compound and at least one second polymerizable compound consisting of a polyfunctional polymerizable compound.

Specifically, for example, it is possible to adopt an embodiment including the following first polymerizable compound and second polymerizable compound.

<First Polymerizable Compound>

The first polymerizable compound is a monofunctional (meth)acrylate monomer, and a monomer having one functional group selected from the group consisting of an epoxy group and an oxetanyl group.

The monofunctional (meth)acrylate monomer may be, for example, acylic acid or methacrylic acid, and derivatives thereof, and more specifically, an aliphatic or aromatic monomer having one polymerizable unsaturated bond (meth)acryloyl group of (meth)acrylic acid in the molecule, and containing 1 to 30 carbon atoms in the alkyl group. Specific examples thereof include the following compounds, but the present invention is not limited thereto.

Examples of the aliphatic monofunctional (meth)acrylate monomer include alkyl (meth)acrylates having 1 to 30 carbon atoms in the alkyl group, such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate;

alkoxyalkyl (meth)acrylates having 2 to 30 carbon atoms in the alkoxyalkyl group, such as butoxyethyl (meth)acrylate;

aminoalkyl (meth)acrylates having a total of 1 to 20 carbon atoms in the (monoalkyl or dialkyl) aminoalkyl group, such as N, N-dimethylaminoethyl (meth)acrylate;

(meth)acrylates of a polyalkylene glycol alkyl ether having 1 to 10 carbon atoms in the alkylene chain and 1 to 10 carbon atoms in the terminal alkyl ether, such as (meth)acrylate of diethylene glycol ethyl ether, (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol;

(meth)acrylates of a polyalkylene glycol aryl ether having 1 to 30 carbon atoms in the alkylene chain and 6 to 20 carbon atoms in the terminal aryl ether, such as (meth)acrylate of hexaethylene glycol phenyl ether;

(meth)acrylates having an alicyclic structure and having a total of 4 to 30 total carbon atoms, such as cyclohexyl (meth)acrylate, dicyclopentanyl (meth)acrylate, isobornyl (meth)acrylate, and methylene oxide-added cyclodecatriene (meth)acrylate; fluorinated alkyl (meth)acrylate having a total of 4 to 30 carbon atoms, such as heptadecafluorodecyl (meth)acrylate;

(meth)acrylates having a hydroxyl group, such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acrylate, and mono(meth)acrylate of glycerol;

(meth)acrylate having a glycidyl group, such as glycidyl (meth)acrylate;

polyethylene glycol mono(meth)acrylates having 1 to 30 carbon atoms in the alkylene chain, such as tetraethylene glycol mono(meth)acrylate, hexaethylene glycol mono(meth)acrylate, and octapropylene glycol mono(meth)acrylate; and

(meth)acrylamides such as (meth)acrylamide, N,N-dimethyl (meth)acrylamide, N-isopropyl (meth)acrylamide, 2-hydroxyethyl (meth)acrylamide, and acryloyl morpholine.

Examples of the aromatic monofunctional acrylate monomer include aralkyl (meth)acrylates having 7 to 20 carbon atoms in the aralkyl group, such as benzyl (meth)acrylate.

Of the first polymerizable compounds, preferred are aliphatic or aromatic alkyl (meth)acrylates having 4 to 30 carbon atoms in the alkyl group, among which preference is given to n-octyl (meth)acrylate, lauryl (meth)acrylate, stearyl (meth)acrylate, cyclohexyl (meth)acrylate, dicyclopentanyl (meth)acrylate, isobornyl (meth)acrylate, and methylene oxide-added cyclodecatriene (meth)acrylate. This is because the dispersibility of quantum dots is improved. As the dispersibility of the quantum dots is improved, the quantity of light that goes straight from the light conversion layer to the light exit surface increases, which is therefore effective for improving front luminance and front contrast.

Examples of the monofunctional epoxy compound having one epoxy group include phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide, 3-vinylcyclohexene oxide, and 4-vinylcyclohexene oxide.

As an example of the monofunctional oxetane compound having one oxetanyl group, a compound obtained by appropriately substituting the epoxy group of the foregoing monofunctional epoxy compound with an oxetane group can be used. With regard to such oxetane ring-containing compounds, among the oxetane compounds described in JP2003-341217A and JP2004-91556A, monofunctional ones can be appropriately selected.

The first polymerizable compound is preferably contained in an amount of 5 to 99.9 parts by mass and more preferably 20 to 85 parts by mass, with respect to 100 parts by mass of the total mass of the first polymerizable compound and the second polymerizable compound.

The reason will be described later.

<Second Polymerizable Compound>

The second polymerizable compound is a polyfunctional (meth)acrylate monomer, and a monomer having two or more functional groups selected from the group consisting of an epoxy group and an oxetanyl group in the molecule.

Among the difunctional or higher polyfunctional (meth)acrylate monomers, preferred examples of difunctional (meth)acrylate monomers include neopentyl glycol di(meth)acrylate, 1,6-hexanediol di(meth)acrylate, 1,9-nananediol di(meth)acrylate, 1,10-decanediol diacrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, tricyclodecane dimethanol diacrylate, and ethoxylated bisphenol A diacrylate.

Among the difunctional or higher polyfunctional (meth)acrylate monomers, preferred examples of trifunctional or higher functional (meth)acrylate monomers include epichlorohydrin (ECH)-modified glycerol tri(meth)acrylate, ethylene oxide (EO)-modified glycerol tri(meth)acrylate, propylene oxide (PO)-modified glycerol tri(meth)acrylate, pentaerythritol triacrylate, pentaerythritol tetraacrylate, EO-modified phosphate triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxy penta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritolethoxy tetra(meth)acrylate, and pentaerythritol tetra(meth)acrylate.

As the polyfunctional monomer, a (meth)acrylate monomer having a urethane bond in the molecule, specifically, an adduct of tolylene diisocyanate (TDI) and hydroxyethyl acrylate, an adduct of isophorone diisocyanate (IPDI) and hydroxyethyl acrylate, an adduct of hexamethylene diisocyanate (HDI) and pentaerythritol triacrylate (PETA), a compound obtained by reacting an isocyanate remaining after preparing an adduct of TDI and PETA with dodecyloxyhydroxypropyl acrylate, an adduct of 6,6 nylon and TDI, an adduct of pentaerythritol, TDI and hydroxyethyl acrylate, or the like can also be used.

As the monomer having two or more functional groups selected from the group consisting of an epoxy group and an oxetanyl group, aliphatic cyclic epoxy compounds, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers; polyglycidyl ethers of polyether polyols obtained by adding one or two or more alkylene oxides to aliphatic polyhydric alcohols such as ethylene glycol, propylene glycol, and glycerin; diglycidyl esters of aliphatic long chain dibasic acids; glycidyl esters of higher fatty acids; compounds containing epoxy cycloalkane; and the like are suitably used.

Examples of commercially available products which can be suitably used as the monomer having two or more functional groups selected from the group consisting of an epoxy group and an oxetanyl group include CELLOXIDE 2021P and CELLOXIDE 8000 (manufactured by Daicel Corporation), and 4-vinylcyclohexene dioxide (manufactured by Sigma Aldrich, Inc.).

Although there are no particular restrictions on the method for producing a monomer having two or more functional groups selected from the group consisting of an epoxy group and an oxetanyl group, the compound can be synthesized with reference to, for example, Literatures such as Fourth Edition Experimental Chemistry Course 20 Organic Synthesis II, p. 213˜, 1992, published by Maruzen KK; Ed. by Alfred Hasfner, The chemistry of heterocyclic compounds-Small Ring Heterocycles part 3 Oxiranes, John & Wiley and Sons, An Interscience Publication, New York, 1985, Yoshimura, Adhesion, vol. 29, No. 12, 32, 1985, Yoshimura, Adhesion, vol. 30, No. 5, 42, 1986, Yoshimura, Adhesion, vol. 30, No. 7, 42, 1986, JP1999-100378A (JP-H11-100378A), JP2906245B, and JP2926262B.

The second polymerizable compound is preferably contained in an amount of 0.1 to 95 parts by mass and more preferably 15 to 80 parts by mass, with respect to 100 parts by mass of the total mass of the first polymerizable compound and the second polymerizable compound. The reason will be described later.

As will be described in detail later, the laminated film 10a has a configuration where the edge face of the functional layer laminate 11 in which the optical functional layer 12 and the gas barrier layer 14 are laminated is sealed with the edge face sealing layer 16a.

In the present invention, the edge face sealing layer 16a is suitably exemplified by a layer formed of a plurality of metal layers as an example. Preferably, a thin metal layer is first formed on the edge face sealing layer 16a by a vapor phase deposition method (vapor phase film forming method) such as a sputtering method, a vacuum vapor deposition method, an ion plating method, or a plasma CVD method.

Here, for example, in the case where a metal layer is formed on the edge face of the optical functional layer 12 having a cured product consisting only of a monofunctional (meth)acrylate compound as a matrix by a sputtering method, the matrix cannot withstand the internal stress of the metal layer, and as a result, defects are generated in the metal layer, and sufficient barrier properties cannot be imparted. On the other hand, in the case where a metal layer is formed on the edge face of the optical functional layer 12 having a cured product consisting only of a polyfunctional (meth)acrylate compound as a matrix by a sputtering method, although there is no defect in the metal layer, it is hard and fragile, so that the smoothness of the edge face is poor, the metal layer cannot cover the edge face uniformly, and as a result, the barrier properties are impaired.

In contrast, in the present invention, as a preferred embodiment, by mixing a monofunctional (meth)acrylate monomer and a polyfunctional (meth)acrylate monomer in the above-mentioned appropriate range, it is capable of withstanding the shrinkage of the film at the time of forming a metal layer, eliminating the defect of the metal layer on the edge face of the optical functional layer 12, and securing the smoothness of the edge face, whereby the edge face sealing layer 16a having high barrier properties at the edge face can be formed.

The elastic modulus at 50° C. of the matrix (cured product) forming the optical functional layer 12 is preferably 1 to 4,000 MPa and more preferably 10 to 3,000 MPa. The reason why the elastic modulus at 50° C. is used is that, for example, in the case of a sputtering method, since the film surface temperature reaches about 50° C. at the time of film formation, it is set as the physical property value of the matrix resistant to film shrinkage. By setting the elastic modulus of the matrix to the above-specified range, defects in the metal layer of the edge sealing layer can be reduced.

The matrix forming the optical functional layer 12, in other words, the polymerizable composition to be the optical functional layer 12 may contain necessary components such as a viscosity modifier and a solvent, if necessary. Note that the polymerizable composition to be the optical functional layer 12 is, in other words, a polymerizable composition for forming the optical functional layer 12.

<Viscosity Modifier>

The polymerizable composition may contain a viscosity modifier, if necessary. The viscosity modifier is preferably a filler having a particle size of 5 to 300 nm. It is also preferred that the viscosity modifier is a thixotropic agent for imparting thixotropy. In the present invention, thixotropy refers to a property of reducing viscosity with increasing shear rate in a liquid composition, and the thixotropic agent refers to a material having a function of imparting thixotropy to a liquid composition by including it in the composition.

Specific examples of the thixotropic agent include fumed silica, alumina, silicon nitride, titanium dioxide, calcium carbonate, zinc oxide, talc, mica, feldspar, kaolinite (kaolin clay), pyrophyllite (pyrophyllite clay), sericite (silk mica), bentonite, smectite-vermiculites (montmorillonite, beidellite, non-tronite, saponite, and the like), organic bentonite, and organic smectite.

The polymerizable composition for forming the optical functional layer 12 preferably has a viscosity of 3 to 50 mPa·s in the case where the shear rate is 500 s⁻¹ and has a viscosity of 100 mPa·s or more in the case where the shear rate is 1 s⁻¹. In order to adjust the viscosity in this way, it is preferable to use a thixotropic agent.

The reason why the viscosity of the polymerizable composition is preferably 3 to 50 mPa·s in the case where the shear rate is 500 s⁻¹ and 100 mPa·s or more in the case where the shear rate is 1 s⁻¹ is as follows.

As a method for producing the functional layer laminate 11, for example, there is a method including a step of preparing two gas barrier layers 14 (gas barrier films) to be described later, a step of applying a polymerizable composition to be the optical functional layer 12 onto the surface of one gas barrier layer 14, a step of attaching another gas barrier layer 14 to the polymerizable composition, and a step of curing the polymerizable composition to form the optical functional layer 12. In the following description, the gas barrier layer onto which the polymerizable composition is applied is referred to as a first base material, and the other gas barrier layer which is attached to the polymerizable composition applied to the first base material is referred to as a second base material.

In this production method, it is preferable to make the film thickness of the coating film uniform by uniformly applying the polymerizable composition so as not to cause coating streaks at the time of applying the polymerizable composition to the first base material, and for this purpose, it is preferred that the viscosity of the polymerizable composition is lower from the viewpoint of coatability and levelability. On the other hand, in the case of attaching the second base material on the polymerizable composition applied to the first base material, in order to uniformly attach the second base material, it is preferred that the resistance to pressure at the time of attaching is high, and from this viewpoint, it is preferred that the viscosity of the polymerizable composition is high.

The above-mentioned shear rate 500 s⁻¹ is a representative value of the shear rate applied to the polymerizable composition applied to the first base material, and the shear rate 1 s⁻¹ is a representative value of the shear rate applied to the polymerizable composition immediately before attaching the second base material to the polymerizable composition. It should be noted that the shear rate 1 s⁻¹ is merely a representative value. In the case where the second base material is attached on the polymerizable composition applied to the first base material, the shear rate applied to the polymerizable composition is approximately 0 s⁻¹ in the case where the first base material and the second base material are attached while being transported at the same speed, and the shear rate applied to the polymerizable composition in the actual production process is not limited to 1 s⁻¹. On the other hand, the shear rate of 500 s⁻¹ is likewise merely a representative value, and the shear rate applied to the polymerizable composition in the actual production process is not limited to 500 s⁻¹.

From the viewpoint of uniform application and attaching, it is preferable to adjust the viscosity of the polymerizable composition such that the viscosity of the polymerizable composition is 3 to 50 mPa·s at a representative value 500 s⁻¹ of shear rate applied to the polymerizable composition at the time of applying the polymerizable composition to the first base material, and the viscosity of the polymerizable composition is 100 mPa·s or more at a representative value 1 s⁻¹ of the shear rate applied to the polymerizable composition immediately before attaching the second base material on the polymerizable composition applied to the first base material.

<Solvent>

The polymerizable composition to be the optical functional layer 12 may contain a solvent if necessary. The type and addition amount of the solvent used in this case are not particularly limited. For example, as the solvent, an organic solvent may be used alone or in combination of two or more thereof.

In addition, the polymerizable composition to be the optical functional layer 12 may contain a fluorine atom-containing compound such as trifluoroethyl (meth)acrylate, pentafluoroethyl (meth)acrylate, (perfluorobutyl)ethyl (meth)acrylate, perfluorobutyl-hydroxypropyl (meth)acrylate, (perfluorohexyl)ethyl (meth)acrylate, octafluoropentyl (meth)acrylate, perfluorooctylethyl (meth)acrylate, or tetrafluoropropyl (meth)acrylate.

Incorporation of such a compound can improve coatability.

In the optical functional layer 12, the amount of the resin serving as a matrix may be appropriately determined according to the type of the functional material included in the optical functional layer 12, and the like.

In the illustrated example, since the optical functional layer 12 is a quantum dot layer, the amount of the resin serving as a matrix is preferably 90 to 99.9 parts by mass and more preferably 92 to 99 parts by mass, with respect to 100 parts by mass of the total amount of the quantum dot layer.

The thickness of the optical functional layer 12 may also be appropriately determined according to the type of the optical functional layer 12, the application of the laminated film 10a, and the like.

In the illustrated example, since the optical functional layer 12 is a quantum dot layer, the thickness of the optical functional layer 12 is preferably 5 to 200 μm and more preferably 10 to 150 μm, from the viewpoint of handleability and luminescence properties.

The thickness of the optical functional layer 12 is intended to be an average thickness, and the average thickness is determined by measuring the thickness of 10 arbitrary points of the quantum dot layer and arithmetically averaging the obtained values.

As a method of forming the optical functional layer 12, various known methods for forming a cured layer formed by dispersing a functional material in a matrix can be used.

For example, in the case where the optical functional layer 12 is a quantum dot layer (fluorescent layer), the optical functional layer 12 can be formed by preparing a polymerizable composition containing quantum dots (phosphors) and at least two or more polymerizable compounds, applying the polymerizable composition onto the gas barrier layer 14, and curing the composition film.

Where appropriate, a polymerization initiator, a silane coupling agent, or the like may be added to the polymerizable composition to be the optical functional layer 12 such as the quantum dot layer.

The gas barrier layer 14 is a layer having gas barrier properties, which is laminated on the main surface of the optical functional layer 12. That is, the gas barrier layer 14 is a member for covering the main surface of the optical functional layer 12 and suppressing infiltration of moisture or oxygen from the main surface of the optical functional layer 12.

In the laminated film 10a of the illustrated example, the functional layer laminate 11 has the gas barrier layers 14 laminated on both main surfaces of the optical functional layer 12, but the present invention is not limited thereto. For example, in the case where the possibility of moisture or oxygen infiltration from one main surface of the functional layer laminate 11 is low, the gas barrier layer 14 may be laminated on only one main surface of the optical functional layer 12. However, in order to more reliably prevent deterioration of the optical functional layer 12 due to moisture or oxygen, as shown in the illustrated example, it is preferred that the gas barrier layers 14 are laminated on both main surfaces of the optical functional layer 12 and the optical functional layer 12 is sandwiched between the two gas barrier layers 14.

The gas barrier layer 14 preferably has a water vapor permeability of 1×10⁻³ g/(m²·day) or less. In addition, the gas barrier layer 14 preferably has an oxygen permeability of 1×10⁻² cc/(m²·day·atm) or less.

By using the gas barrier layer 14 having a low water vapor permeability and a low oxygen permeability, that is, having high gas barrier properties, it is possible to prevent moisture or oxygen from infiltrating into the optical functional layer 12, so that deterioration of the optical functional layer 12 can be prevented more suitably.

As an example, the water vapor permeability was measured by a MOCON method under conditions of a temperature of 40° C. and a relative humidity of 90% RH. In addition, in the case where the water vapor permeability exceeds the measurement limit of the MOCON method, it may be measured by a calcium corrosion method (a method described in JP2005-283561A). In addition, as an example, the oxygen permeability may be measured under conditions of a temperature of 25° C. and a humidity of 60% RH using a measuring apparatus (manufactured by NIPPON API Co., Ltd.) based on an atmospheric pressure ionization mass spectrometry (APIMS) method.

The thickness of the gas barrier layer 14 is preferably 5 to 100 μm, more preferably 10 to 70 μm, and particularly preferably 15 to 55 μm.

By setting the thickness of the gas barrier layer 14 to 5 μm or more, it is preferable from the viewpoint that the thickness of the optical functional layer 12 can be made uniform in the case where the optical functional layer 12 is formed between the two gas barrier layers 14. By setting the thickness of the gas barrier layer 14 to 100 μm or less, it is preferable from the viewpoint that the thickness of the entire laminated film 10a including the optical functional layer 12 can be reduced.

The material for gas barrier layer 14 is not particularly limited, and various materials having desired gas barrier properties can be used.

Here, the gas barrier layer 14 is preferably transparent, and for example, glass, a transparent inorganic crystalline material, a transparent resin material, or the like can be used. Further, the gas barrier layer 14 may be of a rigid sheet shape or a flexible film shape. Furthermore, the gas barrier layer 14 may be an elongate shape capable of being wound, or may be a sheet-like shape previously cut into a predetermined size.

As an example of the gas barrier layer 14, an organic/inorganic lamination type gas barrier layer (an organic/inorganic lamination type gas barrier film) made by forming one or more combinations of an inorganic layer and an organic layer to be a base (formation surface) of this inorganic layer as a barrier layer on a gas barrier support is suitably used.

FIG. 2 is a cross-sectional view conceptually showing an example of such an organic/inorganic lamination type gas barrier layer 14. The gas barrier layer 14 shown in FIG. 2 has a barrier layer 32 formed by laminating an organic layer 34, an inorganic layer 36, and an organic layer 38 in this order, and a gas barrier support 30 supporting the barrier layer 32.

In addition, the gas barrier layer 14 may have at least one inorganic layer 36 on the gas barrier support 30, and preferably has one or more combinations of the inorganic layer 36 and the organic layer 34 serving as the base of the inorganic layer 36. Therefore, the gas barrier layer 14 may have two combinations of the inorganic layer 36 and the underlying organic layer 34, or may have three or more combinations thereof. The organic layer 34 functions as an underlayer for properly forming the inorganic layer 36. A gas barrier film having excellent gas barrier properties can be obtained as the number of lamination of combinations of underlying organic layer 34 and inorganic layer 36 is increased.

In the illustrated example, the outermost layer of the barrier layer 32 is the organic layer 38, but without being limited thereto, the outermost layer may be the inorganic layer 36. Note that the outermost layer of the barrier layer 32 is the layer on the opposite side of the barrier layer 32 to the gas barrier support 30.

Here, basically, the optical functional layer 12 is laminated on the barrier layer 32 side. Therefore, by laminating the outermost layer of the barrier layer 32 as the inorganic layer 36 and laminating the optical functional layer 12 on the barrier layer 32 side, outgas is shielded by the inorganic layer 36 and can be prevented from reaching the optical functional layer 12 even in the case where such outgas is released from the gas barrier support 30 or the organic layer 34.

As the gas barrier support 30 of the gas barrier layer 14, various kinds of materials which are used as a support in a known gas barrier film can be used.

Among them, a film made of various kinds of plastics (polymer materials/resin materials) is suitably used from the viewpoint of being capable of easily achieving thickness reduction and weight reduction, being suitable for flexibility, and the like.

Specifically, resin films made of polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, polymethyl methacrylate resin (PMMA), polycarbonate (PC), polyacrylate, polymethacrylate, polypropylene (PP), polystyrene (PS), acrylonitrile/butadiene/styrene copolymer (ABS), cyclic olefin copolymer (COC), cycloolefin polymer (COP), and triacetyl cellulose (TAC) are suitably exemplified.

The thickness of the gas barrier support 30 may be appropriately set depending on the application and size. Here, according to the study of the present inventors, the thickness of the gas barrier support 30 is preferably about 10 to 100 μm. By setting the thickness of the gas barrier support 30 within this range, preferable results are obtained in terms of weight reduction, thickness reduction, and the like.

In the gas barrier support 30, functions such as reflection prevention, phase difference control, light extraction efficiency improvement, and the like may be imparted to the surface of such a plastic film.

The barrier layer 32 has the inorganic layer 36 mainly exhibiting gas barrier properties, the organic layer 34 serving as an underlayer of the inorganic layer 36, and the organic layer 38 protecting the inorganic layer 36.

The organic layer 34 serves as an underlayer of the inorganic layer 36 which mainly exhibits gas barrier properties in the gas barrier layer 14.

As the organic layer 34, various kinds of materials which are used as the organic layer 34 in a known gas barrier film can be used. For example, the organic layer 34 is a film containing an organic compound as a main component and basically, those formed by crosslinking monomers and/or oligomers can be used.

Since the gas barrier layer 14 has the organic layer 34 serving as the base of the inorganic layer 36, irregularities on the surface of the gas barrier support 30, foreign matters adhered to the surface, and the like can be embedded so that the film formation surface of the inorganic layer 36 can be made proper. As a result, an appropriate inorganic layer 36 free from breakages or cracks can be formed on the entire surface of the film formation surface with no gap. Thereby, a high gas barrier performance is obtained such that the water vapor permeability is 1×10⁻³ g/(m²·day) or less and the oxygen permeability is 1×10⁻² cc/(m²·day·atm) or less.

In addition, since the gas barrier layer 14 has the organic layer 34 serving as the base, the organic layer 34 also acts as a cushion for the inorganic layer 36. Therefore, damage of the inorganic layer 36 can be prevented by the cushion effect of the organic layer 34, for example, in the case where the inorganic layer 36 is subjected to an impact from the outside.

Thereby, in the laminated film 10a, the gas barrier layer 14 appropriately exhibits gas barrier performance, and deterioration of the optical functional layer 12 due to moisture or oxygen can be suitably prevented.

In the gas barrier layer 14, various organic compounds (resins/polymer compounds) can be used as a material for forming the organic layer 34.

Specifically, films of thermoplastic resins such as polyester, acrylic resin, methacrylic resin, methacrylic acid-maleic acid copolymer, polystyrene, transparent fluororesin, polyimide, fluorinated polyimide, polyamide, polyamideimide, polyetherimide, cellulose acylate, polyurethane, polyether ether ketone, polycarbonate, alicyclic polyolefin, polyarylate, polyethersulfone, polysulfone, fluorene ring-modified polycarbonate, alicyclic modified polycarbonate, fluorene ring-modified polyester, acryloyl compound, or polysiloxane, and other organosilicon compounds are suitably exemplified. A plurality of these compounds may be used in combination.

Among them, the organic layer 34 made of a polymer of a radical polymerizable compound and/or a cationic polymerizable compound having an ether group as a functional group is suitable from the viewpoint of excellent glass transition temperature and strength, and the like.

In particular, from the viewpoint of low refractive index, high transparency, excellent optical properties, and the like in addition to the above-mentioned strength, an acrylic resin or methacrylic resin containing a polymer of a monomer or oligomer of acrylate and/or methacrylate as a main component and having a glass transition temperature of 120° C. or higher is suitably exemplified as the organic layer 34. Among these, an acrylic resin or methacrylic resin containing a polymer of a monomer or oligomer of difunctional or higher functional, particularly trifunctional or higher functional acrylate and/or methacrylate, such as dipropylene glycol di(meth)acrylate (DPGDA), trimethylolpropane tri(meth)acrylate (TMPTA), or dipentaerythritol hexa(meth)acrylate (DPHA), as a main component is suitably exemplified. It is also preferable to use a plurality of these acrylic resins or methacrylic resins.

By forming the organic layer 34 with such an acrylic resin or methacrylic resin, the inorganic layer 36 can be formed on a base with a firm skeleton, so that it is possible to form the inorganic layer 36 which is denser and has high gas barrier properties.

The thickness of the organic layer 34 is preferably 1 to 5 μm.

By setting the thickness of the organic layer 34 to 1 μm or more, the film formation surface of the inorganic layer 36 can be made more suitably proper so that an appropriate inorganic layer 36 free from breakages or cracks can be formed over the entire surface of the film formation surface.

Further, by setting the thickness of the organic layer 34 to 5 μm or less, it is possible to suitably prevent occurrence of problems such as cracking of the organic layer 34 and curling of the gas barrier layer 14 due to an excessive thickness of the organic layer 34.

Considering the above points, it is more preferred that the thickness of the organic layer 34 is 1 to 3 μm.

In the case where the gas barrier layer 14 has a plurality of organic layers 34 as the underlayer, the thickness of each organic layer may be the same as or different from each other.

Further, in the case of having a plurality of organic layers 34, the material for forming each organic layer may be the same or different. However, from the viewpoint of productivity and the like, it is preferable to form all the organic layers from the same material.

The organic layer 34 may be formed by a known method such as a coating method or flash evaporation.

In addition, in order to improve the adhesiveness to the inorganic layer 36 serving as the upperlayer of the organic layer 34, the organic layer 34 preferably contains a silane coupling agent.

On the organic layer 34, the inorganic layer 36 is formed using the organic layer 34 as a base. The inorganic layer 36 is a film containing an inorganic compound as a main component and mainly exhibiting gas barrier properties in the gas barrier layer 14.

For the inorganic layer 36, a variety of films exhibiting gas barrier properties and made of a metal oxide, a metal nitride, a metal carbide, a metal carbonitride, or the like can be used.

Specifically, films made of inorganic compounds, for example, a metal oxide such as aluminum oxide, magnesium oxide, tantalum oxide, zirconium oxide, titanium oxide, or indium tin oxide (ITO); a metal nitride such as aluminum nitride; a metal carbide such as aluminum carbide; a silicon oxide such as silicon oxide, silicon oxynitride, silicon oxycarbide, or silicon oxynitride carbide; a silicon nitride such as silicon nitride or silicon nitride carbide; a silicon carbide such as silicon carbide; a hydride thereof; a mixture of two or more thereof; and a hydrogen-containing substance thereof are suitably exemplified. In the present invention, silicon is also regarded as a metal.

In particular, a film made of a silicon compound such as a silicon oxide, a silicon nitride, or a silicon oxynitride is suitably exemplified from the viewpoint of having high transparency and being capable of exhibiting excellent gas barrier properties. Among them, the film made of silicon nitride is suitably exemplified because it has superior gas barrier properties as well as high transparency.

In the case where the gas barrier film has a plurality of inorganic layers 36, the materials for forming the inorganic layer 36 may be different from each other. However, in consideration of productivity and the like, it is preferable to form all the inorganic layers 36 from the same material.

The thickness of the inorganic layer 36 may be appropriately determined depending on the layer forming material, so that the desired gas barrier properties can be exhibited. According to the study of the present inventors, the thickness of the inorganic layer 36 is preferably 10 to 200 nm.

By setting the thickness of the inorganic layer 36 to 10 nm or more, it is possible to form the inorganic layer 36 that stably exhibits sufficient gas barrier performance. In addition, the inorganic layer 36 is generally fragile, and there is a possibility that breaking, cracking, peeling, or the like may occur in the case where the inorganic layer 36 is too thick, but in the case where the thickness of the inorganic layer 36 is set to 200 nm or less, occurrence of cracking can be prevented.

Considering these points, the thickness of the inorganic layer 36 is preferably 10 to 100 nm and more preferably 15 to 75 nm.

In the case where the gas barrier film has a plurality of inorganic layers 36, the thickness of each inorganic layer 36 may be the same or different.

The inorganic layer 36 may be formed by a known method depending on the layer forming material. Specifically, vapor phase deposition methods are suitably exemplified, including plasma CVD such as Capacitively Coupled Plasma (CCP)-Chemical Vapor Deposition (CVD) or Inductively Coupled Plasma (ICP)-CVD, sputtering such as magnetron sputtering or reactive sputtering, vacuum vapor deposition, and the like.

The organic layer 38 is a layer formed on the outermost layer of the barrier layer 32 and is a layer for protecting the inorganic layer 36. In addition, the organic layer 38 may have a function as an adhesion layer with the optical functional layer 12.

For the organic layer 38, various materials similar to those of the above-mentioned organic layer 34 can be used. In addition, those made of a graft copolymer having an acrylic polymer as the main chain and at least one of a urethane polymer having an acryloyl group at the terminal or a urethane oligomer having an acryloyl group at the terminal in the side chain thereof, and having a molecular weight of 10,000 to 3,000,000 and an acrylic equivalent of 500 g/mol or more can also be suitably used for the organic layer 38.

Similarly to the formation of the organic layer 34 described above, the organic layer 38 may be formed by a known method such as a coating method or flash evaporation. The thickness of the organic layer 38 is similar to that of the organic layer 34 described above.

The thickness of the organic layer 38 which is the outermost layer of the barrier layer 32 is preferably 80 to 1,000 nm. By setting the thickness of the organic layer 38 to 80 nm or more, the inorganic layer 36 can be sufficiently protected. In addition, it is preferable to set the thickness of the organic layer 38 to 1,000 nm or less from the viewpoint of preventing cracking, preventing reduction of transmittance, and the like.

From the above viewpoints, the thickness of the organic layer 38 is more preferably 80 to 500 nm.

The organic layer 38 as the protective layer and the organic layer 34 as the underlayer may be formed of the same material or different materials. However, from the viewpoint of productivity and the like, it is preferable to form all the organic layers from the same material.

Further, in order to improve the adhesiveness to the inorganic layer 36 which is the underlayer of the organic layer 38, the organic layer 38 preferably contains a silane coupling agent.

The laminated film 10a of the present invention has a configuration in which the edge face of the functional layer laminate 11 having the optical functional layer 12 and the two gas barrier layers 14 laminated so as to sandwich the optical functional layer 12 is covered with the edge face sealing layer 16a#. Note that the edge face of the functional layer laminate 11 is a face in a direction orthogonal to the lamination direction of the functional layer laminate 11.

Here, in the laminated film 10a of the present invention, the edge face of the functional layer laminate 11 has a surface roughness Ra of 0.1 to 2 μm in a region where the edge face sealing layer 16a is formed. This point will be described in detail later.

As described above, in the laminated film 10a of the present invention, the gas barrier layer 14 prevents oxygen or moisture from infiltrating into the optical functional layer 12 from the main surface of the optical functional layer 12.

On the other hand, the edge face sealing layer 16a prevents moisture or oxygen from infiltrating into the optical functional layer 12 from the edge face of the functional layer laminate 11.

As described above, it has been practiced to laminate gas barrier films on both main surfaces of a quantum dot layer containing quantum dots susceptible to deterioration due to moisture or oxygen to thereby protect the quantum dot layer. However, only protection of both main surfaces of the quantum dot layer with gas barrier films suffers from a problem in that moisture or oxygen infiltrates from the edge face not protected by the gas barrier film, and therefore the quantum dots are deteriorated.

On the other hand, in order to suppress moisture or oxygen from infiltrating from the edge face, a configuration in which the entire surface of the quantum dot layer is protected with the gas barrier film, a configuration in which a protective layer having gas barrier properties is formed in the edge face region of the quantum dot layer sandwiched between the two gas barrier films, a configuration in which the opening of the edge portions of two gas barrier films sandwiching the quantum dot layer is narrowed, and the like have been proposed.

However, there has been a problem that it is very difficult to cover the entire surface of the thin quantum dot layer with a gas barrier film, thereby leading to poor productivity, and in the case where the gas barrier film is folded, the barrier layer is broken and therefore the gas barrier properties are deteriorated.

In the case of a configuration in which a protective layer having gas barrier properties is formed in the edge face region of the quantum dot layer sandwiched between two gas barrier films, there have been problems that a material having high barrier properties cannot be used as the material of the protective layer, then gas barrier properties and durability are not sufficient, and in the case of producing such a laminated film, the productivity was extremely poor because all steps are batch-wise.

Further, in the case of a configuration in which the opening of the edge portion of the two gas barrier films sandwiching the quantum dot layer is narrowed, there have been problems that the thickness of the quantum dot layer at the edge portion becomes thinner, then its function is not sufficiently exhibited at the edge portion, the size of the effective usable area becomes smaller, and the frame portion becomes larger. In general, since the barrier layer having high gas barrier properties is hard and brittle, there have been problems that, in the case where the gas barrier film having such a barrier layer is suddenly bent, the barrier layer is broken, the gas barrier properties are deteriorated, and the entry of moisture or oxygen into the quantum dot layer cannot be suppressed.

On the other hand, the present invention provides a configuration including the functional layer laminate 11 having the optical functional layer 12 and the gas barrier layer 14 laminated on at least one main surface of the optical functional layer 12, and an edge face sealing layer 16a formed so as to cover at least a part of the edge face of the functional layer laminate 11.

By sealing the edge face of the functional layer laminate 11 with the edge face sealing layer 16a, entry of moisture or oxygen into the optical functional layer 12 can be suppressed, consequently deterioration of quantum dots and the like due to moisture or oxygen can be prevented, and the lifetime can be lengthened, so that the durability can be improved.

In addition, since the edge face sealing layer 16a is only formed on the edge face of the functional layer laminate 11, the optical functional layer 12 does not become thin and the gas barrier layer 14 does not become curved, so that a region where the optical functional layer 12 can be effectively used can be largely maintained, and therefore a narrower frame can be realized.

In addition, as will be described in detail later, at the time of forming the edge face sealing layer 16a, since each layer of the edge face sealing layers 16a can be formed in a state where a plurality of functional layer laminates 11 are laminated, a plurality of laminated films 10a can be produced collectively and therefore the productivity can be increased.

Here, in the laminated film 10a of the present invention, the surface roughness Ra of the edge face of the functional layer laminate 11 in the formation region of the edge face sealing layer 16a is 0.1 to 2 μm. As described above, since the edge face sealing layer 16a is formed on the entire edge face of the functional layer laminate 11 in the laminated film 10a of the illustrated example, the surface roughness Ra of the entire edge face of the functional layer laminate 11 is 0.1 to 2 μm.

In the laminated film 10a of the present invention, the edge face sealing layer 16a has a thickness of 1 to 5 μm.

Due to having such a configuration, the laminated film 10a of the present invention makes it possible to cover the edge face of the functional layer laminate 11 with high adhesiveness by an appropriate edge face sealing layer 16a without voids or cracks.

In the following description, the term “formation region of the edge face sealing layer 16a on the edge face of the functional layer laminate 11” is simply referred to as “the edge face of the functional layer laminate 11”.

In the case where peeling occurs between the edge face of the functional layer laminate 11 and the edge face sealing layer 16a, oxygen, moisture, or the like infiltrates from the peeling portion, and therefore it is impossible to prevent entry of oxygen or the like from the edge face of the functional layer laminate 11 into the optical functional layer 12. For that reason, it is necessary that adhesiveness between the edge face of the functional layer laminate 11 and the edge face sealing layer 16a is sufficient.

Here, for the purpose of increasing the adhesiveness between the edge face of the functional layer laminate 11 and the edge face sealing layer 16a, it is preferred that the edge face of the functional layer laminate 11 has a certain degree of surface roughness Ra, in order to obtain a so-called anchoring effect.

On the other hand, in order to prevent entry of oxygen or the like from the edge face of the functional layer laminate 11 into the optical functional layer 12, it is necessary to continuously cover the edge face of the functional layer laminate 11 with the edge face sealing layer 16a having no voids, cracks, or the like. However, on the other hand, in the case where the surface roughness Ra of the edge face of the functional layer laminate 11 is too large, it becomes difficult for the edge face sealing layer 16a to appropriately cover the edge face of the functional layer laminate 11.

In order to continuously cover the edge face of the functional layer laminate 11 with the edge face sealing layer 16a having no voids, cracks, or the like, it is necessary to set the thickness of the edge face sealing layer 16a to a certain thickness or more. On the other hand, in the case where the edge face sealing layer 16a is too thick, a so-called frame region becomes larger and therefore an effective area with respect to the area of the main surface of the laminated film 10a becomes narrower, so that cracks are likely to occur in the edge face sealing layer 16a.

In contrast, in the present invention, by setting the surface roughness Ra of the edge face of the functional layer laminate 11 to 0.1 to 2 μm and setting the thickness of the edge face sealing layer 16a to 1 to 5 μm, the edge face of the functional layer laminate 11 can be covered with high adhesiveness by an appropriate edge face sealing layer 16a having no voids or cracks.

Therefore, according to the present invention, in a laminated film or the like in which an optical functional layer is sandwiched between gas barrier layers, such as a quantum dot film in which a quantum dot layer is sandwiched between gas barrier layers, a high quality laminated film, which achieves both high durability capable of preventing deterioration of the optical functional layer 12 due to oxygen or moisture for a long time and narrowing of the frame, has been realized.

In the case where the surface roughness Ra of the edge face of the functional layer laminate 11 is less than 0.1 μm, the anchoring effect is not sufficiently exhibited, so a region having insufficient adhesiveness is generated between the edge face of the functional layer laminate 11 and the edge face sealing layer 16a. As a result, oxygen or moisture infiltrates from the defect portion between the edge face of the functional layer laminate 11 and the edge face sealing layer 16a, which is caused by peeling, damage, or the like, and deteriorates the optical functional layer 12.

In the case where the surface roughness Ra of the edge face of the functional layer laminate 11 exceeds 2 μm, even in the case where the edge face sealing layer 16a is thickened, the edge face sealing layer 16a cannot sufficiently follow the edge face of the functional layer laminate 11 and therefore pinholes and voids are generated in the edge face sealing layer 16a. This is believed to be due to the fact that the edge face of the functional layer laminate 11 becomes excessively rough so that the film formation by a vapor phase deposition method or a liquid phase deposition method for providing the edge face sealing layer 16a is beyond the limit of the form follow-up.

Considering the above points, the surface roughness Ra of the edge face of the functional layer laminate 11 is 0.1 to 2 μm and preferably 0.5 to 1 μm.

In the present invention, the surface roughness Ra (arithmetic average roughness Ra) of the edge face of the functional layer laminate 11 can be measured, for example, by non-contact surface shape measurement (for example, Micromap, Vertscan 2.0, Vertscan 3.0, or the like, manufactured by Ryoka Systems Co., Ltd.) in optical interferometry. Alternatively, the surface roughness Ra of the edge face of the functional layer laminate 11 can be measured by contact surface shape measurement in accordance with JIS B 0601 (2001) (JIS: Japanese Industrial Standards).

In the case where the surface roughness Ra of the edge face of the functional layer laminate 11 is measured in a state having the edge face sealing layer 16a, for example, the laminated film 10a is cut at a line orthogonal to the edge face of the functional layer laminate 11, a cross section including the edge face of the functional layer laminate 11 is taken, and this cross section is photographed with a scanning electron microscope or the like, and the photographed image is analyzed to detect the profile of the edge face of the functional layer laminate 11. Then, from the detected profile of the edge face, the surface roughness Ra of the edge face of the functional layer laminate 11 can be measured in accordance with JIS B 0601 (2001).

On the other hand, in the case where the thickness of the edge face sealing layer 16a is less than 1 μm, even in the case where the surface roughness Ra of the edge face of the functional layer laminate 11 is small, the edge face sealing layer 16a cannot sufficiently follow the edge face of the functional layer laminate 11, so that pinholes or voids are generated in the edge face sealing layer 16a.

In the case where the thickness of the edge face sealing layer 16a exceeds 5 μm, there are problems that the frame region becomes larger and therefore the effective area with respect to the area of the laminated film 10a becomes smaller, and cracks and the like are likely to occur in the edge face sealing layer 16a. In the latter case, it is believed to be due to the fact that an internal stress is generated at the time of providing the edge face sealing layer 16a, and a force to contract in the in-plane direction of the edge face sealing layer 16a is exerted.

Considering the above points, the thickness of the edge face sealing layer 16a is 1 to 5 μm and preferably 2 to 4 μm.

In other words, the thickness of the edge face sealing layer 16a is a size of the edge face sealing layer 16a in the direction perpendicular to the edge face of the functional layer laminate 11.

The edge face sealing layer 16a preferably has an oxygen permeability of 1×10⁻² cc/(m²·day·atm) or less and more preferably 1×10⁻³ cc/(m²·day·atm) or less.

By forming the edge face sealing layer 16a having a low oxygen permeability, that is, high gas barrier properties on the edge face of the functional layer laminate 11, the penetration of moisture or oxygen into the optical functional layer 12 is more suitably prevented, and therefore deterioration of the optical functional layer 12 can be more suitably prevented.

Further, the edge face sealing layer 16a may be formed so as to cover at least a part of the edge face of the functional layer laminate 11, but it is preferred that the edge face sealing layer 16a is formed to cover the entire circumference of the edge face.

As described above, in the case where the functional layer laminate 11 has a rectangular planar shape, it is sufficient that the edge face sealing layer 16a is formed on at least one edge face or a part thereof, and it is preferred that the edge face sealing layer 16a is formed on all of the four edge faces.

The shape of the main surface of the functional layer laminate 11 (the shape of the laminated film 10a) is not limited to a rectangular shape, and may be various shapes such as a square shape, a circular shape, and a polygonal shape. Therefore, it is sufficient that the edge face protective layer is formed so as to cover at least a part of the edge face, and it is preferred that the edge face protective layer is formed so as to cover the entire circumference of the edge face.

In the laminated film 10a of the present invention, the edge face sealing layer for sealing the edge face of the functional layer laminate 11 may be a single layer or a plurality of layers. The edge face sealing layer consisting of a plurality of layers may have a two-layer structure or a layer structure of three or more layers.

For example, as shown in the edge face sealing layer 16a of the laminated film shown in FIG. 1, the edge face sealing layer consisting of a plurality of layers may be a two-layer structure made of the underlayer 18 formed on the edge face of the functional layer laminate 11, and a shielding layer 20 formed on the underlayer 18 and mainly exhibiting gas barrier properties in the edge face sealing layer 16a. In the edge face sealing layer, the “on” refers to a surface of each layer, that is, a surface on the side opposite to the functional layer laminate 11.

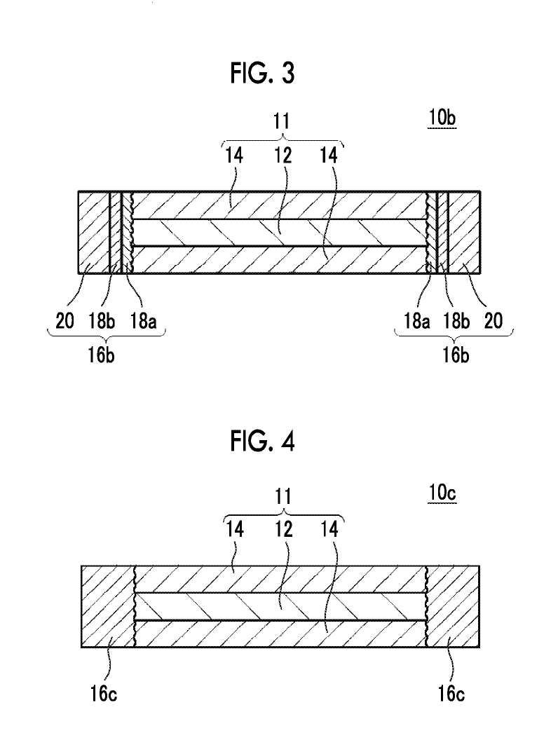

As in the laminated film 10b shown in FIG. 3, the edge face sealing layer may be a three-layer structure which has the first underlayer 18a on the edge face of the functional layer laminate 11, the second underlayer 18b on the first underlayer 18a, and the shielding layer 20 on the second underlayer 18b.

That is, the underlayer is a layer formed between the shielding layer 20 mainly exhibiting gas barrier properties and the edge face of the functional layer laminate 1I.

Furthermore, in the laminated film of the present invention, the edge face sealing layer may have a topcoat layer, such as a protective layer, a hard coat layer, an optical compensation layer, or a transparent conductive layer, on the shielding layer 20.

In the laminated film of the present invention, the shielding layer 20 may have a multilayer structure.

For example, the shielding layer 20 may be configured to sandwich an interlayer having a small gas barrier function between layers exhibiting gas barrier properties. In addition, the shielding layer 20 having one or a plurality of combinations of an organic layer to be a base, an inorganic layer exhibiting gas barrier properties, and an organic layer to be an underlayer (formation surface) of the inorganic layer, as exemplified in the above-mentioned gas barrier layer 14, is also illustrated. In this case, all of the combinations of the organic layer and the inorganic layer become the shielding layer 20, and in the case where an organic layer is formed on the edge face of the functional layer laminate 11, this organic layer becomes a layer which also functions as the underlayer 18, a part of the shielding layer 20, and the underlayer 18.

As shown in FIGS. 1 and 3, since the edge face sealing layer is laminated on the edge face of the functional layer laminate 11, the lamination direction of each layer constituting the edge face sealing layer (underlayer 18, first underlayer 18a, second underlayer 18b, and shielding layer 20) is a direction perpendicular to the edge face of the functional layer laminate 11 and is a direction orthogonal to the lamination direction of the functional layer laminate 11.

Further, in the case where the edge face sealing layer has a multilayer structure, the thickness of the edge face sealing layer 16 is the total thickness of all the layers. That is, in the case of the laminated film 10a shown in FIG. 1, the thickness of the edge face sealing layer 16a is a total thickness of the underlayer 18 and the shielding layer 20, and in the case of the laminated film 10b shown in FIG. 3, the thickness of the edge face sealing layer 16b is a total thickness of the first underlayer 18a, the second underlayer 18b, and the shielding layer 20. Further, in the case where the edge face sealing layer has a topcoat layer, the thickness of the edge face sealing layer is a thickness including the thickness of the topcoat layer.

In the laminated film 10a shown in FIG. 1, both the underlayer 18 and the shielding layer 20 are suitably exemplified by a metal layer (a layer made of a metal). Also in the laminated film 10b shown in FIG. 3, the first underlayer 18a, the second underlayer 18b, and the shielding layer 20 are each suitably exemplified by a metal layer.

Also, in the case where the shielding layer 20 is a metal layer, the shielding layer 20 is preferably a metal plating layer formed by electrolytic plating. By making the shielding layer 20 to be a metal plating layer, it is possible to form a dense metal layer having a desired thickness as the shielding layer 20 by covering the entire surface of the formation surface with high coverage (coatability), so that an edge face sealing layer having high gas barrier properties can be formed.

In addition, the underlayer 18, the first underlayer 18a, and the second underlayer 18b are preferably metal layers formed by any one of a sputtering method, a vacuum vapor deposition method, an ion plating method, and a plasma CVD method. Among them, a metal layer formed by a sputtering method providing good adhesiveness and capable of performing low temperature film formation is more preferable.

Since the functional layer laminate 11 is mainly made of resin, an appropriate metal layer cannot be formed due to no conductive path, even in the case where it is attempted to form a metal plating layer as the shielding layer 20 directly on the edge face of the functional layer laminate 11 by electrolytic plating.

On the other hand, by providing the metal layer on the edge face of the functional layer laminate 11, the adhesiveness between the functional layer laminate 11 and the edge face sealing layer can be improved. In addition, by providing a metal layer under the shielding layer 20, this metal layer acts as an electrode, so that it is possible to suitably form the metal plating layer and it is possible to form the shielding layer 20 by metal plating which is dense and has high gas barrier properties. Further, during the plating treatment, the first layer protects the functional layer laminate 11, and therefore the functional layer laminate 11 can be prevented from being damaged.

Furthermore, by providing the first underlayer 18a and the second underlayer 18b like the edge face sealing layer 16b shown in FIG. 3, it is possible to form the edge face sealing layer 16b having superior adhesiveness and gas barrier properties by strengthening the adhesiveness to the edge face of the functional layer laminate 11 by the first underlayer 18a and securing high conductivity by the second underlayer 18b.

It can also be contemplated that the edge face sealing layer is formed of only one metal layer formed by any one of a sputtering method, a vacuum vapor deposition method, an ion plating method, and a plasma CVD method. However, in this case, although satisfactory adhesiveness to the functional layer laminate 11 can be obtained, it is difficult to form a thicker thickness, or it is inevitable to make it thin because a thicker thickness leads to very poor productivity. Therefore, it is impossible to form an edge face sealing layer having a uniform thickness and no pinholes or voids on the edge face of the functional layer laminate 11, so that sufficient gas barrier properties cannot be obtained.

On the other hand, by providing a metallic underlayer formed by any one of a sputtering method, a vacuum vapor deposition method, an ion plating method, and a plasma CVD method, and a metal plating layer as the shielding layer 20, the adhesiveness to the functional layer laminate is improved and sufficient gas barrier properties can be obtained.

It is preferred that the thickness of the shielding layer 20 made of metal plating is thicker than the thickness of the underlayer 18 and the total thickness of the first underlayer 18a and the second underlayer 18b. That is, it is preferred that the thickness of the shielding layer 20 made of metal plating is thicker than the thickness of the underlayer made of a metal.

By making the thickness of the shielding layer 20 made of metal plating thicker than that of the underlayer made of a metal, sufficient gas barrier properties can be more reliably exhibited.

The thickness of the underlayer 18, the thickness of the first underlayer 18a, the thickness of the second underlayer 18b, and the thickness of the shielding layer 20 are each a thickness in the direction perpendicular to the edge face of the functional layer laminate 11.

Specifically, the thickness of the underlayer 18 is preferably 0.001 to 0.5 μm and more preferably 0.01 to 0.3 μm, from the viewpoint of conductivity, adhesiveness to the functional layer laminate 11, productivity, and the like.

In the case of forming the first underlayer 18a and the second underlayer 18b, the thickness of the first underlayer 18a is preferably 0.001 to 0.5 μm and more preferably 0.01 to 0.3 μm, and the thickness of the second underlayer 18b is preferably 0.001 to 0.5 μm and more preferably 0.01 to 0.3 μm, from the viewpoint of conductivity, adhesiveness to the functional layer laminate 11, productivity, and the like.

On the other hand, the thickness of the shielding layer 20 made of metal plating is preferably 0.1 to 5 μm and more preferably 1 to 5 μm from the viewpoint of securing gas barrier properties, productivity, and the like.

In the case of forming the underlayer 18, the first underlayer 18a and the second underlayer 18b from a metal, a variety of metals capable of forming a film by any one of a sputtering method, a vacuum vapor deposition method, an ion plating method, and a plasma CVD method as described above can be used as the layer forming material.

Specifically, it is preferable to use at least one selected from the group consisting of aluminum, titanium, chromium, copper, and nickel, or an alloy containing at least one of these metals. Among them, from the viewpoint of adhesiveness, titanium is suitably exemplified as the material for the first underlayer 18a.

By forming the underlayer 18, the first underlayer 18a, and the second underlayer 18b from these metals, it is preferred from the viewpoint that the adhesiveness between the edge face of the functional layer laminate 11 and the edge face sealing layer can be increased, and the shielding layer 20 can be preferably formed by electroplating.

In addition, a variety of metals capable of being electrolytically plated can be used as the material for forming the shielding layer 20.

Specifically, it is preferable to use at least one selected from the group consisting of aluminum, titanium, chromium, nickel, tin, copper, silver, and gold, or an alloy containing at least one of these metals.

By forming the shielding layer 20 from these metals, it is possible to improve the gas barrier properties of the edge face sealing layer by forming the shielding layer 20 which is dense and has high gas barrier properties by electrolytic plating.

The material for forming the underlayer 18 and the shielding layer 20 may be the same metal or different metals.

The material for forming the first underlayer 18a, the second underlayer 18b, and the shielding layer 20 may be the same metal or different metals. For example, the second underlayer 18b and the shielding layer 20 may be formed of the same metal such as copper, and only the first underlayer 18a may be formed of a different metal such as titanium.

In the case where the edge face sealing layer is formed of a multilayered metal layer, other configurations can be used.

For example, it may be a configuration in which the shielding layer 20 formed by electrolytic plating is formed on the underlayer 18 made of a metal, and a metal layer as a topcoat layer is formed on the shielding layer 20 by any one of a sputtering method, a vacuum vapor deposition method, an ion plating method, and a plasma CVD method in the same manner as the underlayer 18.

In the laminated film 10a of the present invention, in the case where the shielding layer 20 of the edge face sealing layer 16a is a metal plating layer, the underlayer 18 may be an organic layer. That is, in the laminated film 10a of the present invention, the edge face sealing layer 16b having the organic layer as the underlayer 18 and the metal layer formed by the metal plating as the shielding layer 20 can also be suitably used.

Alternatively, in the laminated film of the present invention, in the case where the shielding layer 20 of the edge face sealing layer 16a is a metal plating layer, the second underlayer 18b made of a metal as before or further a third underlayer made of a metal is formed on the organic layer as the first underlayer 18a (see FIG. 3), and the shielding layer 20 by metal plating may be formed thereon. That is, in the laminated film of the present invention, an edge face sealing layer having an organic layer as the first underlayer 18a, a metal layer as the second underlayer 18b, and a metal layer by metal plating as the shielding layer 20, or further a metal layer as the third underlayer between the second underlayer 18b and the shielding layer 20 can also be suitably used.

By providing an organic layer as the underlayer 18 (first underlayer 18a), the formation surface of the shielding layer 20 is properly formed so as to cover the entire edge face of the functional layer laminate 11 to form an appropriate shielding layer 20 so that an edge face sealing layer having high gas barrier properties can be formed.

Since, by providing an organic layer as the underlayer 18, the organic layer acts also as a cushion, damage of the inorganic layer 36 can be prevented by the cushion effect of the underlayer 18, in the case where the shielding layer 20 is subjected to an impact from the outside.

Thereby, in the laminated film 10a, the gas barrier layer 14 appropriately exhibits gas barrier performance, and therefore deterioration of the optical functional layer 12 due to moisture or oxygen can be suitably prevented.

As a material for forming the organic layer as the underlayer 18, various organic compounds (resins/polymer compounds) can be used.

Specifically, films of thermoplastic resins such as polyester, acrylic resin, methacrylic resin, methacrylic acid-maleic acid copolymer, polystyrene, transparent fluororesin, polyimide, fluorinated polyimide, polyamide, polyamideimide, polyetherimide, cellulose acylate, polyurethane, polyether ether ketone, polycarbonate, alicyclic polyolefin, polyarylate, polyethersulfone, polysulfone, fluorene ring-modified polycarbonate, alicyclic modified polycarbonate, fluorene ring-modified polyester, and acryloyl compound, or polysiloxane, and other organosilicon compounds are suitably exemplified. A plurality of these compounds may be used in combination.

Among them, the organic layer formed of a polymer of a radical polymerizable compound and/or a cationic polymerizable compound having an ether group as a functional group is suitable from the viewpoint of excellent glass transition temperature and strength, and the like.

In particular, from the viewpoint of low refractive index, high transparency and excellent optical properties, and the like in addition to the above-mentioned strength, an acrylic resin or methacrylic resin containing a polymer of a monomer or oligomer of acrylate and/or methacrylate as a main component and having a glass transition temperature of 120° C. or higher is suitably exemplified as the organic layer 34. Among these, an acrylic resin or methacrylic resin containing a polymer of a monomer or oligomer of difunctional or higher functional, particularly trifunctional or higher functional acrylate and/or methacrylate, such as dipropylene glycol di(meth)acrylate (DPGDA), trimethylolpropane tri(meth)acrylate (TMPTA), or dipentaerythritol hexa(meth)acrylate (DPHA), as a main component is suitably exemplified. It is also preferable to use a plurality of these acrylic resins or methacrylic resins.

By forming the organic layer as the underlayer 18 with such an acrylic resin or methacrylic resin, the shielding layer 20 can be formed on a base with a firm skeleton, so that it is possible to form the shielding layer 20 which is denser and has high gas barrier properties.

The thickness of the organic layer as the underlayer 18 is preferably 1 to 3 μm.

By setting the thickness of the organic layer to 1 μm or more, it is possible to form the proper shielding layer 20 over the entire surface of the film formation surface by appropriately setting the film formation surface of the shielding layer 20.

By setting the thickness of the organic layer to 3 μm or less, it is preferable from the viewpoint that narrowing of the frame can be achieved, and occurrence of cracks in the organic layer and poor adhesion due to internal stress can be suitably prevented.

As described later, in the case of providing a plurality of organic layers as the underlayer 18, the thickness of each organic layer may be the same as or different from each other.

In the case of having a plurality of organic layers, the materials for forming the respective organic layers may be the same or different, but from the viewpoint of productivity and the like, it is preferable to form all the organic layers from the same material.

The organic layer as the underlayer 18 may be formed by a known method such as a coating method or flash evaporation.

In addition, in order to improve the adhesiveness to the shielding layer 20, the organic layer 34 as the underlayer 18 preferably contains a silane coupling agent.

In the laminated film 10a of the present invention, in the case where an organic layer is used as the underlayer 18, an inorganic layer can also be suitably used as the shielding layer 20. That is, in the laminated film 10a of the present invention, the edge face sealing layer 16a having an organic layer as the underlayer 18 and an inorganic layer as the shielding layer 20 can also be suitably used.

That is, in the edge face sealing layer, the above-mentioned organic/inorganic laminated structure in the gas barrier layer 14 can also be suitably used. In addition, the edge face sealing layer having the organic/inorganic laminated structure may have a plurality of combinations of an organic layer and an inorganic layer.

For the inorganic layer as the shielding layer 20, a variety of films exhibiting gas barrier properties and made of an inorganic compound such as a metal oxide, a metal nitride, a metal carbide, or a metal carbonitride can be used.

Specifically, films made of inorganic compounds, for example, a metal oxide such as aluminum oxide, magnesium oxide, tantalum oxide, zirconium oxide, titanium oxide, or indium tin oxide (ITO); a metal nitride such as aluminum nitride; a metal carbide such as aluminum carbide; a silicon oxide such as silicon oxide, silicon oxynitride, silicon oxycarbide, or silicon oxynitride carbide; a silicon nitride such as silicon nitride or silicon nitride carbide; a silicon carbide such as silicon carbide; a hydride thereof; a mixture of two or more thereof; and a hydrogen-containing substance thereof are suitably exemplified. In the present invention, silicon is also regarded as a metal as described above.

In particular, a film made of a silicon compound such as a silicon oxide, a silicon nitride, a silicon oxynitride, or a silicon oxide is suitably exemplified from the viewpoint capable of exhibiting excellent gas barrier properties. Among them, the film made of silicon nitride is suitably exemplified because it has superior gas barrier properties as well as high transparency.

In the case where the shielding layer 20 of the edge face sealing layer has a plurality of inorganic layers, the materials for forming the inorganic layer may be different from each other. However, considering productivity and the like, it is preferable to form all the inorganic layers from the same material.

The thickness of the inorganic layer as the shielding layer 20 may be appropriately determined depending on the layer forming material, so that the desired gas barrier properties can be exhibited. According to the study of the present inventors, the thickness of the inorganic layer is preferably 10 to 200 nm.

By setting the thickness of the inorganic layer as the shielding layer 20 to 10 nm or more, it is possible to form the inorganic layer that stably exhibits sufficient gas barrier performance. In addition, the inorganic layer is generally fragile, and there is a possibility that breaking, cracking, peeling, or the like may occur in the case where the inorganic layer is too thick, but in the case where the thickness of the inorganic layer is set to 200 nm or less, occurrence of cracking can be prevented.

Considering these points, the thickness of the inorganic layer as the shielding layer 20 is preferably 10 to 100 nm and more preferably 15 to 75 nm.

In the case where the shielding layer 20 has a plurality of inorganic layers, the thickness of each inorganic layer may be the same or different.

The inorganic layer may be formed by a known method depending on the layer forming material. Specifically, vapor phase deposition methods are suitably exemplified, including plasma CVD such as CCP-CVD or ICP-CVD, sputtering such as magnetron sputtering or reactive sputtering, vacuum vapor deposition, and the like.

For the inorganic layer as the shielding layer 20, a coating type inorganic layer using polysilazane or the like can also be used.

As such a coating type inorganic layer, the inorganic layers described in JP2011-161302A, JP2012-56130A, and JP2012-61659A can be suitably used.

In the case where an inorganic layer is used as the shielding layer 20, an organic layer serving as a protective layer may be formed as a topcoat layer on the surface of the shielding layer 20.

For the organic layer as the topcoat layer, a variety of organic layers similar to the organic layer as the above-mentioned underlayer 18 can be used.

The thickness of the organic layer as the topcoat layer is preferably 80 to 1,000 nm. By setting the thickness of the organic layer to 80 nm or more, the shielding layer 20 can be sufficiently protected. In addition, the thickness of the organic layer is preferably set to 1,000 nm or less from the viewpoint of preventing cracking and preventing reduction of transmittance, and the like. From the above viewpoints, the thickness of the organic layer as the topcoat layer is more preferably 80 to 500 nm.

The organic layer as the topcoat layer and the organic layer as the underlayer 18 may be the same or different in layer forming materials. However, from the viewpoint of productivity and the like, it is preferable to form all the organic layers from the same material.

In order to improve the adhesiveness to the shielding layer 20 serving as the underlayer, the organic layer as the topcoat layer preferably contains a silane coupling agent.

As described above, in the present invention, as in the laminated film 10c conceptually shown in FIG. 4, the edge face sealing layer 16c may be a single layer. That is, the edge face sealing layer 16c may be made of only the shielding layer.

As the single-layer edge face sealing layer 16c, an edge face sealing layer made of a resin having gas barrier properties can be used.

The resin layer having gas barrier properties and serving as the edge face sealing layer 16c can be formed by a variety of known resin materials capable of forming the edge face sealing layer 16c which exhibits desired gas barrier properties. In the following description, the “resin layer having gas barrier properties” is also referred to as “gas barrier resin layer”.

Here, in general, the gas barrier resin layer is formed in such a manner that a composition containing a curable compound (monomer, dimer, trimer, oligomer, polymer, or the like) mainly constituting the edge face sealing layer 16c, that is, mainly the gas barrier resin layer, an additive such as a crosslinking agent or a surfactant added if necessary, an organic solvent, and the like is prepared, this composition is applied onto the formation surface of the edge face sealing layer 16c, the composition is dried, and the curable compound to be mainly a gas barrier resin layer is polymerized (crosslinked/cured) by ultraviolet irradiation, heating, or the like, if necessary.

In the gas barrier resin layer, a compound having a polymerizable group can be widely adopted as the curable compound. The type of the polymerizable group is not particularly limited and is preferably a (meth)acrylate group, a vinyl group, or an epoxy group, more preferably a (meth)acrylate group, and still more preferably an acrylate group. With respect to a polymerizable monomer having two or more polymerizable groups, the respective polymerizable groups may be the same or different.

<(Meth)Acrylate-Based Compounds>

From the viewpoint of transparency, adhesiveness, or the like of a cured film after curing, a (meth)acrylate compound such as a monofunctional or polyfunctional (meth)acrylate monomer, a polymer or prepolymer thereof, or the like is preferable.

<<Difunctional Ones>>

The polymerizable monomer having two polymerizable groups may be, for example, a difunctional polymerizable unsaturated monomer having two ethylenically unsaturated bond-containing groups. The difunctional polymerizable unsaturated monomer is suitable for allowing a composition to have a low viscosity. In the present invention, preferred is a (meth)acrylate-based compound which is excellent in reactivity and which has no problems associated with a remaining catalyst and the like.

In particular, neopentyl glycol di(meth)acrylate, 1,9-nonanediol di(meth)acrylate, dipropylene glycol di(meth)acrylate, tripropylene glycol di(meth)acrylate, tetraethylene glycol di(meth)acrylate, hydroxypivalate neopentyl glycol di(meth)acrylate, polyethylene glycol di(meth)acrylate, dicyclopentenyl (meth)acrylate, dicyclopentenyl oxyethyl(meth)acrylate, dicyclopentanyl di(meth)acrylate, or the like is suitably used in the present invention.

The amount of the difunctional (meth)acrylate monomer to be used is preferably 5 parts by mass or more and more preferably 10 to 80 parts by mass with respect to 100 parts by mass of the total amount of the curable compound contained in the composition, from the viewpoint of adjusting the viscosity of the coating liquid to a preferred range.

<<Tri- or Higher Functional Ones>>

The polymerizable monomer having three or more polymerizable groups may be, for example, a polyfunctional polymerizable unsaturated monomer having three or more ethylenically unsaturated bond-containing groups. Such a polyfunctional polymerizable unsaturated monomer is excellent in terms of imparting mechanical strength. In the present invention, preferred is a (meth)acrylate-based compound which is excellent in reactivity and which has no problems associated with a remaining catalyst and the like.

Specifically, ECH-modified glycerol tri(meth)acrylate, EO-modified glycerol tri(meth)acrylate, PO-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxy penta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritolethoxy tetra(meth)acrylate, pentaerythritol tetra(meth)acrylate, or the like is suitable.

Among them, EO-modified glycerol tri(meth)acrylate, PO-modified glycerol tri(meth)acrylate, trimethylolpropane tri(meth)acrylate, EO-modified trimethylolpropane tri(meth)acrylate, PO-modified trimethylolpropane tri(meth)acrylate, dipentaerythritol hexa(meth)acrylate, dipentaerythritol penta(meth)acrylate, pentaerythritolethoxy tetra(meth)acrylate, or pentaerythritol tetra(meth)acrylate is suitably used in the present invention.

The amount of the polyfunctional (meth)acrylate monomer to be used is preferably 5 parts by mass or more from the viewpoint of the coating film hardness of the optical functional layer after curing, and preferably 95 parts by mass or less from the viewpoint of suppressing gelation of the coating liquid, with respect to 100 parts by mass of the total amount of the curable compound contained in the coating liquid.

<<Monofunctional Ones>>

A monofunctional (meth)acrylate monomer may be, for example, acrylic acid or methacrylic acid, or a derivative thereof, more specifically, a monomer having one polymerizable unsaturated bond ((meth)acryloyl group) of (meth)acrylic acid in the molecule. Specific examples thereof include the following compounds, but the present invention is not limited thereto.

Examples include alkyl (meth)acrylates having 1 to 30 carbon atoms in the alkyl group, such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate; aralkyl (meth)acrylates having 7 to 20 carbon atoms in the aralkyl group, such as benzyl (meth)acrylate; alkoxyalkyl (meth)acrylates having 2 to 30 carbon atoms in the alkoxyalkyl group, such as butoxyethyl (meth)acrylate; aminoalkyl (meth)acrylates having a total of 1 to 20 carbon atoms in the (monoalkyl or dialkyl)aminoalkyl group, such as N,N-dimethylaminoethyl (meth)acrylate; polyalkylene glycol alkyl ether (meth)acrylates having 1 to 10 carbon atoms in the alkylene chain and having 1 to 10 carbon atoms in the terminal alkyl ether, such as diethylene glycol ethyl ether (meth)acrylate, triethylene glycol butyl ether (meth)acrylate, tetraethylene glycol monomethyl ether (meth)acrylate, hexaethylene glycol monomethyl ether (meth)acrylate, octaethylene glycol monomethyl ether (meth)acrylate, nonaethylene glycol monomethyl ether (meth)acrylate, dipropylene glycol monomethyl ether (meth)acrylate, heptapropylene glycol monomethyl ether (meth)acrylate, and tetraethylene glycol monoethyl ether (meth)acrylate; polyalkylene glycol aryl ether (meth)acrylates having 1 to 30 carbon atoms in the alkylene chain and having 6 to 20 carbon atoms in the terminal aryl ether, such as hexaethylene glycol phenyl ether (meth)acrylate; (meth)acrylates having an alicyclic structure and having a total of 4 to 30 carbon atoms, such as cyclohexyl (meth)acrylate, dicyclopentanyl (meth)acrylate, isobornyl (meth)acrylate, and methylene oxide addition cyclodecatriene (meth)acrylate; fluorinated alkyl (meth)acrylates having a total of 4 to 30 carbon atoms, such as heptadecafluorodecyl (meth)acrylate; (meth)acrylates having a hydroxyl group, such as 2-hydroxyethyl (meth)acrylate, 3-hydroxypropyl (meth)acrylate, 4-hydroxybutyl (meth)acrylate, triethylene glycol mono(meth)acrylate, tetraethylene glycol mono(meth)acrylate, hexaethylene glycol mono(meth)acrylate, octapropylene glycol mono(meth)acrylate, and glycerol mono or di(meth)acrylate; (meth)acrylates having a glycidyl group, such as glycidyl (meth)acrylate; polyethylene glycol mono(meth)acrylates having 1 to 30 carbon atoms in the alkylene chain, such as tetraethylene glycol mono(meth)acrylate, hexaethylene glycol mono(meth)acrylate, and octapropylene glycol mono(meth)acrylate; and (meth)acrylamides such as (meth)acrylamide, N,N-dimethyl (meth)acrylamide, N-isopropyl (meth)acrylamide, 2-hydroxyethyl (meth)acrylamide, and acryloylmorpholine.

The amount of the monofunctional (meth)acrylate monomer to be used is preferably 10 parts by mass or more and more preferably 10 to 80 parts by mass with respect to 100 parts by mass of the total amount of the curable compound contained in the coating liquid, from the viewpoint of adjusting the viscosity of the coating liquid to a preferable range.

<Epoxy-Based Compounds and Others>

The polymerizable monomer for use in the gas barrier resin layer may be, for example, a compound having a cyclic group such as a ring-opening polymerizable cyclic ether group such as an epoxy group or an oxetanyl group. Such a compound may be more preferably, for example, a compound having a compound (epoxy compound) having an epoxy group. Use of the compound having an epoxy group or an oxetanyl group in combination with the (meth)acrylate-based compound tends to improve adhesiveness to the barrier layer.

Examples of the compound having an epoxy group include polyglycidyl esters of polybasic acids, polyglycidyl ethers of polyhydric alcohols, polyglycidyl ethers of polyoxyalkylene glycols, polyglycidyl ethers of aromatic polyols, hydrogenated compounds of polyglycidyl ethers of aromatic polyols, urethane polyepoxy compounds, and epoxidized polybutadienes. These compounds may be used alone or in combination of two or more thereof.

Examples of other compounds having an epoxy group, which may be preferably used, include aliphatic cyclic epoxy compounds, bisphenol A diglycidyl ethers, bisphenol F diglycidyl ethers, bisphenol S diglycidyl ethers, brominated bisphenol A diglycidyl ethers, brominated bisphenol F diglycidyl ethers, brominated bisphenol S diglycidyl ethers, hydrogenerated bisphenol A diglycidyl ethers, hydrogenerated bisphenol F diglycidyl ethers, hydrogenerated bisphenol S diglycidyl ethers, 1,4-butanediol diglycidyl ethers, 1,6-hexanediol diglycidyl ethers, glycerin triglycidyl ethers, trimethylolpropane triglycidyl ethers, polyethylene glycol diglycidyl ethers, and polypropylene glycol diglycidyl ethers; polyglycidyl ethers of polyether polyols, obtained by adding one or two or more alkylene oxides to an aliphatic polyhydric alcohol such as ethylene glycol, propylene glycol, or glycerin; diglycidyl esters of aliphatic long chain dibasic acids; monoglycidyl ethers of aliphatic higher alcohols; monoglycidyl ethers of polyether alcohols, obtained by adding an alkylene oxide to phenol, cresol, butyl phenol, or these compounds; and glycidyl esters of higher fatty acids.

Among these components, aliphatic cyclic epoxy compounds, bisphenol A diglycidyl ethers, bisphenol F diglycidyl ethers, hydrogenerated bisphenol A diglycidyl ethers, hydrogenerated bisphenol F diglycidyl ethers, 1,4-butanediol diglycidyl ethers, 1,6-hexanediol diglycidyl ethers, glycerin triglycidyl ethers, trimethylolpropane triglycidyl ethers, neopentyl glycol diglycidyl ethers, polyethylene glycol diglycidyl ethers, and polypropylene glycol diglycidyl ethers are preferable.

Examples of commercially available products which can be suitably used as the compound having an epoxy group or an oxetanyl group include UVR-6216 (manufactured by Union Carbide Corporation), glycidol, AOEX24, CYCLOMER A200, CELLOXIDE 2021P and CELLOXIDE 8000 (all manufactured by Daicel Corporation), 4-vinylcyclohexene dioxide manufactured by Sigma Aldrich, Inc., EPIKOTE 828, EPIKOTE 812, EPIKOTE 1031, EPIKOTE 872 and EPIKOTE CT508 (all manufactured by Yuka Shell Epoxy K.K.), and KRM-2400, KRM-2410, KRM-2408, KRM-2490, KRM-2720 and KRM-2750 (all manufactured by Asahi Denka Kogyo K.K.). These compounds may be used alone or in combination of two or more thereof.

Although there are no particular restrictions on the production method of such a compound having an epoxy group or an oxetanyl group, the compound can be synthesized with reference to, for example, Literatures such as Fourth Edition Experimental Chemistry Course 20 Organic Synthesis 11, p. 213, 1992, published by Maruzen KK; Ed. by Alfred Hasfner, The chemistry of heterocyclic compounds-Small Ring Heterocycles part 3 Oxiranes, John & Wiley and Sons, An Interscience Publication, New York, 1985, Yoshimura, Adhesion, vol. 29, No. 12, 32, 1985, Yoshimura, Adhesion, vol. 30, No. 5, 42, 1986, Yoshimura, Adhesion, vol. 30, No. 7, 42, 1986, JP1999-100378A (JP-H11-100378A), JP2906245B, and JP2926262B.

As the curable compound for use in the gas barrier resin layer, a vinyl ether compound may also be used.

As the vinyl ether compound, a known vinyl ether compound can be appropriately selected, and, for example, the compound described in paragraph [0057] of JP2009-73078A may be preferably adopted.

Such a vinyl ether compound can be synthesized by, for example, the method described in Stephen. C. Lapin, Polymers Paint Color Journal. 179 (4237), 321 (1988), namely, by a reaction of a polyhydric alcohol or a polyhydric phenol with acetylene, or a reaction of a polyhydric alcohol or a polyhydric phenol with a halogenated alkyl vinyl ether, and such method and reactions may be used alone or in combination of two or more thereof.

From the viewpoint of lowering the viscosity and increasing the hardness, it is also possible to use a silsesquioxane compound having a reactive group described in JP2009-73078A in the composition for forming a gas barrier resin layer.

<Filler>

The gas barrier resin layer preferably contains a filler from the viewpoint of reducing oxygen permeability and moisture permeability.

Those having any shape and form such as a spherical shape, a needle shape, a line shape, a flat shape, a layer shape, an amorphous shape, a porous shape, and an aggregate can be used as the filler, but in view of exhibiting the effect of lengthening a penetration path length, the filler preferably has a needle shape, a flat shape, or a layer shape. From the viewpoint that the film thickness can be made thin, it is more preferable to have a needle shape or a layer shape.

As a material for forming the filler, an inorganic compound and an organic compound can be used without any limitation, but an inorganic compound and a crystalline organic polymer are preferable from the viewpoint of enhancing oxygen blocking properties.

As the inorganic compound filler, various layered compounds usable as thixotropic agents to be described separately are suitably used. Carbon materials such as carbon nanotubes and graphene can also be suitably used.

As the crystalline organic polymer filler, needle-like crystals of crystalline cellulose known as cellulose nanofibers or cellulose nanowhiskers, granulated or fibrous materials of other crystalline polymers, for example, polyamide, polyimide, polyvinyl alcohol, and ethylene-vinyl alcohol copolymers, whiskers, and the like can be used.

The content of these fillers may be appropriately determined depending on the properties and dispersibility of the filler to be used and the degree of expression of the viscosity increasing effect. The viscosity increasing effect is the function as a thixotropic agent.

In the case where the amount of the filler is too small, there is a possibility that the effect of improving the gas barrier properties cannot be sufficiently obtained, and in the case where the amount of the filler is excessive, there is a possibility that the gas barrier properties may be impaired by the occurrence of cracks or voids due to brittleness deterioration. These fillers may also serve as a thixotropic agent, and an optimum addition amount thereof should be set in view of the addition amount of the above-mentioned thixotropic agent.

Considering the above points, the content of the filler is preferably 0.1 to 100 parts by mass, more preferably 0.2 to 50 parts by mass, and particularly preferably 0.5 to 20 parts by mass, with respect to 100 parts by mass of the curable compound in the composition for forming a gas barrier resin layer.

<Thixotropic Agent>

The composition for forming a gas barrier resin layer may contain a thixotropic agent, if necessary.

The thixotropic agent is an inorganic compound or an organic compound.

<<Inorganic Compound>>

One preferred aspect of the thixotropic agent is a thixotropic agent of an inorganic compound, and, for example, a needle-like compound, a chain-like compound, a flattened compound, or a layered compound can be preferably used. Among them, a layered compound is preferable.

The layered compound is not particularly limited and examples thereof include talc, mica, feldspar, kaolinite (kaolin clay), pyrophyllite (pyrophyllite clay), sericite (silk mica), bentonite, smectite-vermiculites (montmorillonite, beidellite, non-tronite, saponite, and the like), organic bentonite, and organic smectite.

These compounds may be used alone or in combination of two or more thereof. Examples of commercially available layered compounds include, as inorganic compounds, CROWN CLAY, BURGESS CLAY #60, BURGESS CLAY KF and OPTIWHITE (all manufactured by Shiraishi Kogyo Kaisha Ltd.), KAOLIN JP-100, NN KAOLIN CLAY, ST KAOLIN CLAY AND HARDSEAL (all manufactured by Tsuchiya Kaolin Ind., Ltd.), ASP-072, SATINTONPLUS, TRANSLINK 37 and HYDROUSDELAMI NCD (all manufactured by Angel Hard Corporation), SY KAOLIN, OS CLAY, HA CLAY and MC HARD CLAY (all manufactured by Maruo Calcium Co., Ltd.), RUCENTITE SWN, RUCENTITE SAN, RUCENTITE STN, RUCENTITE SEN and RUCENTITE SPN (all manufactured by Co-op Chemical Co., Ltd.), SUMECTON (manufactured by Kunimine Industries Co., Ltd.), BENGEL, BENGEL FW, ESBEN, ESBEN 74, ORGANITE and ORGANITE T (all manufactured by Hojun Co., Ltd.), HODAKA JIRUSHI, ORBEN, 250M, BENTONE 34 and BENTONE 38 (all manufactured by Wilbur-Ellis Company), and LAPONITE, LAPONITE RD and LAPONITE RDS (all manufactured by Nippon Silica Industrial Co., Ltd.). These compounds may also be dispersed in a solvent.

The thixotropic agent to be added to the composition for forming a gas barrier resin layer is, among layered inorganic compounds, a silicate compound represented by xM(I)₂O.ySiO₂ (also including a compound corresponding to M(II)O or M(III)₂O₃ having an oxidation number of 2 or 3; x and y represent a positive number), and a further preferred compound is a swellable layered clay mineral such as hectorite, bentonite, smectite, or vermiculite.

Particularly preferably, a layered (clay) compound modified with an organic cation can be suitably used, and examples thereof include compounds in which a sodium ion in sodium magnesium silicate (hectorite) is exchanged with an ammonium ion which will be described below. The layered compound modified with an organic cation is one in which an interlayer cation such as sodium of a silicate compound is exchanged with an organic cation compound.

Examples of the ammonium ion include a monoalkyltrimethylammonium ion, a dialkyldimethylammonium ion, and a trialkylmethylammonium ion, each having an alkyl chain having 6 to 18 carbon atoms, a dipolyoxyethylene-palm oil-alkylmethylammonium ion and a bis(2-hydroxyethyl)-palm oil-alkylmethylammonium ion, each having 4 to 18 oxyethylene chains, and a polyoxypropylene methyldiethylammonium ion having 4 to 25 oxopropylene chains. These ammonium ions may be used alone or in combination of two or more thereof.

The method for producing an organic cation-modified silicate mineral in which a sodium ion of sodium magnesium silicate is exchanged with an ammonium ion is as follows: sodium magnesium silicate is dispersed in water and sufficiently stirred, and thereafter allowed to stand for 16 hours or more to prepare a 4% by mass dispersion liquid; while this dispersion liquid is stirred, a desired ammonium salt is added in an amount of 30% by mass to 200% by mass relative to sodium magnesium silicate; after the addition, cation exchange takes place, and hectorite containing an ammonium salt between the layers becomes insoluble in water and precipitates, and therefore the precipitate is collected by filtration and dried. In the preparation, heating may also be carried out for the purpose of accelerating the dispersion.

Commercially available products of the alkylammonium-modified silicate mineral include RUCENTITE SAN, RUCENTITE SAN-316, RUCENTITE STN, RUCENTITE SEN, and RUCENTITE SPN (all manufactured by Co-op Chemical Co., Ltd.), which may be used alone or in combination of two or more thereof.

In the present invention, silica, alumina, silicon nitride, titanium dioxide, calcium carbonate, zinc oxide, or the like can be used as the thixotropic agent of an inorganic compound. These compounds may also be subjected to a treatment to adjust hydrophilicity or hydrophobicity on the surface, if necessary.

<<Organic Compound>>

A thixotropic agent of an organic compound can also be used as the thixotropic agent.

Examples of the thixotropic agent of an organic compound include an oxidized polyolefin and a modified urea.

The oxidized polyolefin may be independently prepared in-house or may be a commercially available product. Examples of commercially available products include DISPARLON 4200-20 (manufactured by Kusumoto Chemicals, Ltd.) and FLOWNON SA300 (manufactured by Kyoeisha Chemical Co., Ltd.).

The modified urea is a reaction product of an isocyanate monomer or an adduct thereof with an organic amine. The modified urea may be independently prepared in-house or may be a commercially available product. The commercially available product may be, for example, BYK 410 (manufactured by BYK Additives & Instruments).

<<Content>>

The content of the thixotropic agent in the coating liquid is preferably 0.15 to 20 parts by mass, more preferably 0.2 to 10 parts by mass, and particularly preferably 0.2 to 8 parts by mass, with respect to 100 parts by mass of the curable compound. In particular, in the case of the thixotropic agent of an inorganic compound, the content of 20 parts by mass or less with respect to 100 parts by mass of the curable compound tends to improve brittleness.

<Polymerization Initiator>

The composition for forming a gas barrier resin layer may contain a polymerization initiator, if necessary.

A known polymerization initiator can be used as the polymerization initiator. With respect to the polymerization initiator, for example, reference can be made to paragraph [0037] of JP2013-043382A. The polymerization initiator is preferably in an amount of 0.1% by mol or more and more preferably 0.5% to 2% by mol based on the total amount of the curable compound contained in the composition. In addition, the polymerization initiator is preferably contained in an amount of 0.1% to 10% by mass and more preferably 0.2% to 8% by mass, as the percentage by mass in the composition excluding the volatile organic solvent.

<Silane Coupling Agent>

The composition for forming a gas barrier resin layer may contain a silane coupling agent, if necessary.

Since the gas barrier resin layer formed from the composition containing a silane coupling agent has strong adhesiveness to the edge face of the functional layer laminate 11 by the silane coupling agent, excellent durability can be obtained.

For the silane coupling agent, a known silane coupling agent can be used without any limitation. From the viewpoint of adhesiveness, a preferred silane coupling agent may be, for example, a silane coupling agent represented by General Formula (1) described in JP2013-43382A.

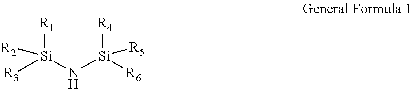

(In General Formula (1), R₁ to R₆ are each independently a substituted or unsubstituted alkyl group or aryl group, provided that at least one of R₁, R₂, R₃, R₄, R₅, or R₆ is a substituent containing a radical polymerizable carbon-carbon double bond.)

R₁ to R₆ are preferably an unsubstituted alkyl group or an unsubstituted aryl group, except for a case where R₁ to R₆ are a substituent containing a radical polymerizable carbon-carbon double bond. The alkyl group is preferably an alkyl group having 1 to 6 carbon atoms and more preferably a methyl group. The aryl group is preferably a phenyl group. R₁ to R₆ are each particularly preferably a methyl group.

It is preferred that at least one of R₁, R₂, R₃, R₄, R₅, or R₆ has a substituent containing a radical polymerizable carbon-carbon double bond, and two of R₁ to R₆ are a substituent containing a radical polymerizable carbon-carbon double bond. Further, it is particularly preferred that among R₁ to R₃, the number of those having a substituent containing a radical polymerizable carbon-carbon double bond is 1, and among R₄ to R₆, the number of those having a substituent containing a radical polymerizable carbon-carbon double bond is 1.

In the case where the silane coupling agent represented by General Formula (1) has two or more substituents containing a radical polymerizable carbon-carbon double bond, the respective substituents may be the same or different, and are preferably the same.

It is preferred that the substituent containing a radical polymerizable carbon-carbon double bond is represented by —X-Y where X is a single bond, an alkylene group having 1 to 6 carbon atoms, or an arylene group, preferably a single bond, a methylene group, an ethylene group, a propylene group, or a phenylene group; and Y is a radical polymerizable carbon-carbon double bond group, preferably an acryloyloxy group, a methacryloyloxy group, an acryloylamino group, a methacryloylamino group, a vinyl group, a propenyl group, a vinyloxy group, or a vinylsulfonyl group, and more preferably a (meth)acryloyloxy group.

R₁ to R₆ may also have a substituent other than the substituent containing a radical polymerizable carbon-carbon double bond. Examples of such a substituent include alkyl groups (for example, a methyl group, an ethyl group, an isopropyl group, a tert-butyl group, an n-octyl group, an n-decyl group, an n-hexadecyl group, a cyclopropyl group, a cyclopentyl group, and a cyclohexyl group), aryl groups (for example, a phenyl group and a naphthyl group), halogen atoms (for example, fluorine, chlorine, bromine, and iodine), acyl groups (for example, an acetyl group, a benzoyl group, a formyl group, and a pivaloyl group), acyloxy groups (for example, an acetoxy group, an acryloyloxy group, and a methacryloyloxy group), alkoxycarbonyl groups (for example, a methoxycarbonyl group and an ethoxycarbonyl group), aryloxycarbonyl groups (for example, a phenyloxycarbonyl group), and sulfonyl groups (for example, a methanesulfonyl group and a benzenesulfonyl group).

The silane coupling agent is contained in the coating liquid in the range of preferably 1% to 30% by mass, more preferably 3% to 30% by mass, and still more preferably 5% to 25% by mass, from the viewpoint of further improving the adhesiveness to the adjacent layer.

Even in the configuration of using such a barrier resin layer as a shielding layer, as shown in FIG. 1, an edge face sealing layer 16a having a two-layer structure having the underlayer 18 may be used.

That is, in the laminated film 10a of the present invention, the edge face sealing layer 16a having an organic layer as the underlayer 18 and a barrier resin layer as the shielding layer 20 can also be suitably used.

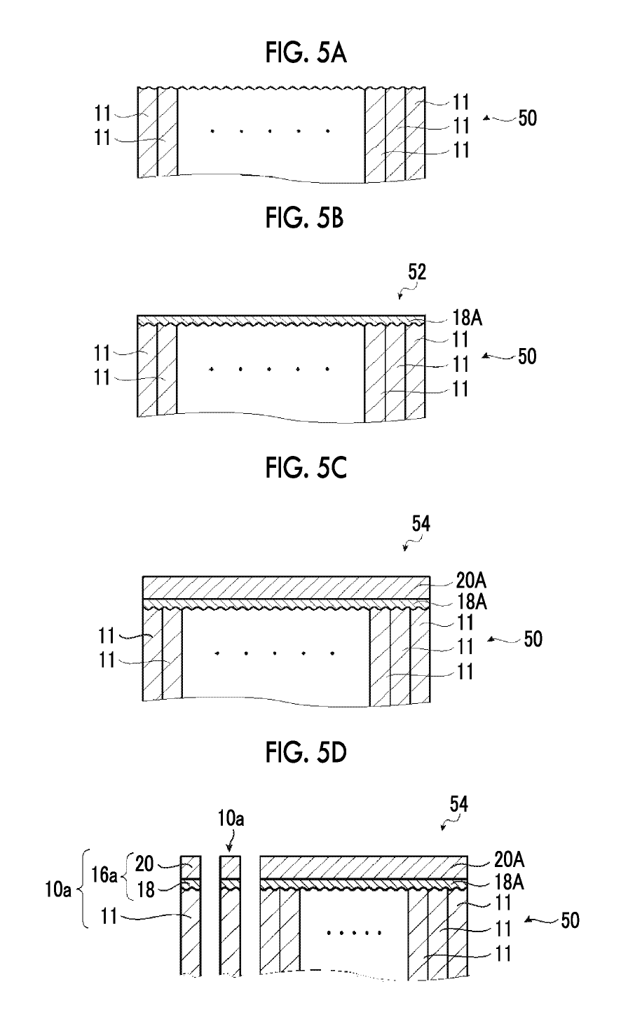

Hereinafter, an example of a method for producing the laminated film of the present invention will be described with reference to the conceptual views of FIGS. 5A to 5D.

Note that the description of the production method below will be conducted with the laminated film 10a shown in FIG. 1 as a representative example, but a laminated film having another configuration can also be produced according to this production method.

First, a large number of functional layer laminates 11 each having the optical functional layer 12 and two gas barrier layers 14 laminated on both main surfaces of the optical functional layer 12 are prepared.

As described above, for example, the functional layer laminate 11 can be prepared by preparing a polymerizable composition in which quantum dots, a resin serving as a matrix, and a solvent are mixed, applying the polymerizable composition onto the gas barrier layer 14, laminating the gas barrier layer 14 on the polymerizable composition, and curing the polymerizable composition by ultraviolet irradiation or the like to form the optical functional layer 12.

It should be noted that the functional layer laminate 11 may be produced by a so-called single sheet type method in which the functional layer laminate 11 is produced one by one, or may be produced by a so-called roll-to-roll method in which a polymerizable composition is applied onto the gas barrier layer 14 while transporting the elongated gas barrier layer 14 in the longitudinal direction, the gas barrier layer 14 is laminated on the polymerizable composition, and the polymerizable composition is cured to thereby continuously produce the functional layer laminate 11. In the following description, the “roll-to-roll” is also referred to as “R to R”.

After thus preparing the functional layer laminate 11, a plurality of functional layer laminates are laminated to produce a laminate 50 (see FIG. 5A).

The number of the functional layer laminates 11 in the laminate 50 is not particularly limited and may be appropriately set depending on the size of the apparatus forming the underlayer 18A, the thickness of the functional layer laminate 11, and the like, but it is suitably about 500 to 4000.

Here, by performing one or more of selection of cutting method or cutting conditions of the functional layer laminate 11 and processing of the edge face of the laminate 50, that is, the edge face of the functional layer laminate 1, as shown in FIG. 5A, the surface roughness Ra of the edge face of the functional layer laminate 11 of the laminate 50 can be made 0.1 to 2 μm.

As a method for controlling the surface roughness of the edge face of the functional layer laminate 11, for example, a method of cutting the edge face of the laminate 50 by a method which does not produce scrap marks on the edge face as in laser cutting, or a method of cutting, polishing, and melting the edge face of the laminate 50 after cutting with a blade is exemplified.

As a specific example, a method of cutting the edge face of the laminate 50 with a microtome (for example, RETORATOME REM-710 or the like, manufactured by Yamato Kohki Industrial Co., Ltd.) and controlling the surface roughness Ra is exemplified. More specifically, the flatness increases as the angle at which the cutting blade of the microtome hits the laminate 50, that is, the angle formed by the blade traveling direction and the blade face is closer to orthogonal. The angle at which the cutting edge hits the laminate 50 is preferably 70° to 110°, more preferably 80° to 100°, and still more preferably 85° to 95°.

Conventionally, the angle formed by the blade face and the direction orthogonal to the traveling direction of the blade is sometimes called “blade angle”.

In addition, the surface roughness Ra can also be controlled by properly controlling the width (cutting amount) of the removed portion by cutting. The cutting amount is preferably 1 to 20 μm and more preferably 5 to 15 μm.

It is estimated that the change in the surface roughness due to such cutting conditions is caused by the distortion of the cutting surface generated in the case where the cutting blade hits the laminate 50 or the rocking of the cutting surface due to the twisting. Therefore, it is preferable to appropriately determine the conditions according to the balance of hardness or brittleness/viscosity of the laminate to be applied.

Further, the surface roughness Ra can be further reduced by a polishing treatment. For the polishing treatment, a commercially available planar apparatus for use in a mirror surface treatment of a light guide plate can be used.

Cutting waste generated at the time of cutting and polishing waste generated at the time of polishing treatment cause defects in the subsequent edge face sealing layer 16a sputtering step or plating step, so it is preferable to eliminate such waste as soon as possible after cutting.

Examples of the step of removing cutting waste and polishing waste include a method by air spraying or ultrasonic washing in a state of being immersed in a washing liquid, a method by lamination and peeling of an adhesive sheet, a wiping-up method, and the like.

In this manner, in the case where the edge face of the laminate 50, that is, the edge face of the functional layer laminate 11 has a desired surface roughness Ra, as shown in FIG. 5B, an underlayer 18A to be the underlayer 18 is formed on the edge face of the laminate 50. As the material for forming the underlayer 18A, as described above, at least one selected from the group consisting of aluminum, titanium, chromium, copper, and nickel, or an alloy containing at least one of these metals is exemplified.

As described above, any one of a sputtering method, a vacuum vapor deposition method, an ion plating method, an electroless plating method, and a plasma CVD method is suitably used as the method for forming the underlayer 18A.

There are no particular restrictions on the treatment method, treatment conditions, and the like in a sputtering method, a vacuum vapor deposition method, an ion plating method, an electroless plating method, or a plasma CVD method at the time of forming the underlayer 18A, and the underlayer 18A may be formed according to conventionally known treatment methods and treatment conditions, depending on the layer forming material or the like

Further, in a region other than the edge face of the functional layer laminate 11, that is, in a region where the underlayer 18A is not formed, a masking treatment or the like is carried out by a known method so that the underlayer 18A is formed only on the edge face of the functional layer laminate 11.

Next, as shown in FIG. 5C, a shielding layer 20A to be the shielding layer 20 is formed on the underlayer 18A of the laminate 52 having the underlayer 18A formed on the cut surface. As described above, at least one selected from the group consisting of aluminum, titanium, chromium, nickel, tin, copper, silver, and gold, or an alloy containing at least one of these metals is exemplified as the material for forming the shielding layer 20A.

As described above, electrolytic plating is preferable as a method for forming the shielding layer 20A.

There are no particular restrictions on the treatment method, treatment conditions, and the like of the electrolytic plating treatment in the case of forming the shielding layer 20A, and the shielding layer 20A may be formed according to known treatment methods and treatment conditions, depending on the layer forming material or the like.

Next, as shown in FIG. 5D, the laminate 54 on which the shielding layer 20A is formed is separated for each functional layer laminate 11, and the functional layer laminate 11 in which the edge face sealing layer 16a is formed on the edge face, that is, the laminated film 10a can be obtained.

A method for separating the laminated film 10a from the laminate 54 is not particularly limited, but a method of shearing by applying an external force such as bending or twisting in the horizontal direction to the surface, onto the laminate 54 having the shielding layer 20A formed thereon, a method of inserting a sharp tip such as a blade into the interface of the functional layer laminate 11, and the like are exemplified.

From the viewpoint of preventing peeling, chipping or cracking of the edge face sealing layer 16a, and the like, it is preferable to separate the laminated film 10a by means of shearing through application of external force.

In this production method, the surface roughness Ra of the edge face of the functional layer laminate 11 can be adjusted in a state where a plurality of functional layer laminates 11 are laminated, and at the time of forming each layer of the edge face sealing layers 16a, since each layer of the edge face sealing layers 16a can be formed in a state where a plurality of functional layer laminates 11 are laminated, a plurality of laminated films 10a can be produced collectively and therefore the productivity can be increased.

In the above examples, the method for producing the laminated film 10a having the edge face sealing layer 16a having a two-layer structure has been described as an example, but in the case of an edge face sealing layer having a structure of three or more layers, a step of forming a metal layer or the like may be further carried out between the step of forming the underlayer 18 and the step of forming the shielding layer 20.

In the case of the edge face sealing layer 16c having a single layer structure as shown in FIG. 4, similarly, an edge face sealing layer 16c such as a gas barrier resin layer is formed on the edge face of the laminate 50, and then the individual laminated films 10c may be separated as shown in FIG. 5D.

Further, in the case where the edge face sealing layer includes a metal layer, an anticorrosive treatment or the like may be carried out in order to suppress rusting of the metal layer.

Although the laminated film of the present invention has been described in detail above, the present invention is not limited to the foregoing embodiments, and various improvements and modifications may be made without departing from the scope and spirit of the present invention.

### EXAMPLES

Hereinafter, the present invention will be described in more detail with reference to specific examples of the present invention. It should be noted that the present invention is not limited to the Examples described below, and the materials, amount of use, proportion, treatment content, treatment procedure, and the like shown in the following Examples are appropriately changed without departing from the spirit of the present invention.

<Production of Gas Barrier Layer 14>

As the gas barrier layer 14, a gas barrier film in which an organic layer 34, an inorganic layer 36, and an organic layer 38 were formed in this order on a gas barrier support 30, shown in FIG. 2, was produced.

<<Gas Barrier Support 30>>

As the gas barrier support 30, a polyethylene terephthalate film (PET film, trade name: COSMOSHINE A4300 manufactured by Toyobo Co., Ltd., thickness of 50 μm, width of 1,000 mm, and length of 100 m) was used.

<<Formation of Organic Layer 34>>

The organic layer 34 was formed on one main surface of the gas barrier support 30.

First, a polymerizable composition for forming the organic layer 34 was prepared as follows.

Trimethylolpropane triacrylate (TMPTA, manufactured by Daicel-Cytec Co., Ltd.) and a photopolymerization initiator (ESACUREKTO46, manufactured by Lamberti S.p.A.) were prepared, were weighed to have a mass ratio of 95:5, and were dissolved in methyl ethyl ketone, and thus, a polymerizable composition having a concentration of solid contents of 15% by mass was prepared.

Using this polymerizable composition, the organic layer 34 was formed on one surface of the gas barrier support 30 in an R to R manner by a general film forming apparatus that performs film formation by a coating method.

First, the composition was applied onto the gas barrier support 30 in an R to R manner by using a die coater. After that, the gas barrier support 30 was passed through a drying zone at 50° C. for 3 minutes, and then irradiated with ultraviolet rays (integrated irradiation dose of about 600 mJ/cm²) to cure the polymerizable composition to form the organic layer 34.

A polyethylene film (PE film, PAC2-30-T, manufactured by Sun A. Kaken Co., Ltd.) was attached as a protective film with a pass roll immediately after curing, followed by being transported and wound. The thickness of the formed organic layer 34 was 1 μm.

<<Formation of Inorganic Layer 36>>

Next, an inorganic layer 36 (silicon nitride (SiN) layer) was formed on the surface of the organic layer 34 by using an R to R type CVD apparatus.

Specifically, the laminate having the organic layer 34 formed on the gas barrier support 30 and having the protective film attached on the organic layer 34 was fed out from a sending machine, the protective film was peeled off after being passed through the final film surface touch roll before the formation of the inorganic layer, and an inorganic layer 36 was formed on the exposed organic layer 34 by plasma CVD.

Silane gas (SiH₄), ammonia gas (NH₃), nitrogen gas (N₂), and hydrogen gas (H2) were used as raw material gases. The supply amounts of the gases were set to 160 sccm for the silane gas, 370 sccm for the ammonia gas, 240 sccm for the nitrogen gas, and 590 sccm for the hydrogen gas, respectively. Further, the film forming pressure was set to 40 Pa. The plasma excitation power was set to 2.5 kW at a frequency of 13.56 MHz.

The film thickness of the formed inorganic layer 36 was 50 nm.

<<Formation of Organic Layer 38>>

Next, the organic layer 38 was formed on the surface of the formed inorganic layer 36.

First, a polymerizable composition for forming the organic layer 38 was prepared. Specifically, a urethane bond-containing acrylic polymer (ACRIT 8BR500, manufactured by Taisei Fine Chemical Co., Ltd., weight-average molecular weight of 250,000) and a photopolymerization initiator (IRGACURE 184, manufactured by BASF GmbH) were weighed to have a mass ratio of 95:5, and were dissolved in methyl ethyl ketone, and thus, a polymerizable composition having a concentration of solid contents of 15% by mass was prepared.

Using this polymerizable composition, the organic layer 38 was formed on one surface of the inorganic layer 36 in an R to R manner by a general film forming apparatus that performs film formation by a coating method.

First, the prepared polymerizable composition was applied onto the surface of the inorganic layer 36 using a die coater, and passed through a drying zone at 100° C. for 3 minutes to form the organic layer 38. The thickness of the formed organic layer 38 was 1 μm.

In the pass roll immediately after the composition was dried, the same polyethylene film as before was attached on the surface of the organic layer 38 as a protective film and then wound up.

As described above, the gas barrier layer 14 in which the organic layer 34, the inorganic layer 36, and the organic layer 38 were laminated in this order on the gas barrier support 30 was produced.

The oxygen permeability of the produced gas barrier layer 14 was measured by an APIMS method. As a result, the oxygen permeability at a temperature of 25° C. and a humidity of 60% RH was 1×10⁻³ cc/(m²·day·atm).

<Production of Functional Layer Laminate 11>

Two gas barrier layers 14 prepared as described above were prepared.

After removing the protective film from one gas barrier layer 14, a polymerizable composition for forming the optical functional layer 12 was applied onto the organic layer 38 of the gas barrier layer 14 to form a coating film. Further, after removing the protective film from the other gas barrier layer 14, the gas barrier layer 14 was laminated on the coating film with the organic layer 38 facing the coating film.

In this way, after a laminate in which a polymerizable composition for forming the optical functional layer 12 had been sandwiched between two gas barrier layers was prepared, UV irradiation was carried out under a nitrogen atmosphere to cure the coating film, whereby the optical functional layer 12 was formed. Thereby, a laminate in which the gas barrier layers 14 were laminated on both surfaces of the optical functional layer 12 was produced.

The composition of the polymerizable composition for forming the optical functional layer 12 is as follows.

<<Composition of Polymerizable Composition>>

| | | |
|---|---|---|
| Toluene dispersion liquid | 10 | parts by mass |
| (emission maximum: 520 nm) of quantum dots 1 | | |
| Toluene dispersion liquid | 1 | part by mass |
| (emission maximum: 630 nm) of quantum dots 2 | | |
| Lauryl acrylate | 2.4 | parts by mass |
| 1,9-nonanediol diacrylate | 0.54 | parts by mass |
| Photopolymerization initiator | 0.003 | parts by mass |

(IRGACURE 819, Manufactured by BASF GmbH)

For the quantum dots 1 and 2, nanocrystals having the following core-shell structure (InP/ZnS) were used.
Quantum dots 1: INP 530-10 (manufactured by NN-Labs, LLC)
Quantum dots 2: INP 620-10 (manufactured by NN-Labs, LLC)

The viscosity of the polymerizable composition for forming an optical functional layer was 50 mPa·s.

<<Sheet Processing>>

The laminate in which the gas barrier layers 14 were laminated on both surfaces of the optical functional layer 12 was punched into a sheet using a Thomson blade having a blade edge angle of 17° to obtain an A4 size functional layer laminate 11.

### Example 1

Using such a functional layer laminate 11, a laminated film 10b having an edge face sealing layer 16b having a three-layer structure as shown in FIG. 3 was produced as follows.

<Adjustment of Surface Roughness Ra of Edge Face>

1,000 layers of the produced functional layer laminate 11 were laminated to obtain a laminate, and then, using a microtome (RETORATOME REM-710, manufactured by Yamato Kohki Industrial Co., Ltd.) under conditions of a blade angle of 0° and a cutting amount of 10 μm, the four edge faces of the laminate, that is, the four edge faces of the functional layer laminate 11 were cut to adjust the surface roughness Ra of the edge face (see FIG. 5A).

The surface roughness Ra of the edge face of the laminate, that is, the edge face of the functional layer laminate 11 was measured by a non-contact surface shape measuring apparatus (Vertscan 2.0, manufactured by Ryoka Systems Co., Ltd.) in optical interferometry.

As a result, the surface roughness Ra of the edge face of the laminate was 0.6 μm.

<Formation of Edge Face Sealing Layer 16b>

<<Formation of First Underlayer>>

Using a general sputtering apparatus, a first underlayer made of titanium was formed on the edge face of the laminate treated at the edge face (see FIG. 5B). Titanium was used as a target and argon was used as a discharge gas. The film forming pressure was 0.5 Pa, and the film forming output was 400 W.

The formed film thickness was 10 nm.

<<Formation of Second Underlayer 18b>>

Subsequently, a second underlayer having a film thickness of 75 nm was formed on the first underlayer in the same manner as the formation of the first underlayer, except that the target was changed from titanium to copper.

<<Formation of Shielding Layer 20>>

Further, a shielding layer was formed on the second underlayer as follows.

First, the laminate on which the first underlayer and the second underlayer were formed was washed with pure water and degreased by immersing the laminate in a bath filled with a commercially available surfactant for 20 seconds. Next, after washing with water, the laminate was immersed in a 5% sulfuric acid aqueous solution for 5 seconds to carry out an acid activity treatment, and then washed again with water.

The washed laminate was fixed in a jig, and electrical continuity was confirmed with a tester. Then, the laminate was immersed in a 5% nitric acid aqueous solution for 10 seconds to carry out an acid activity treatment, and subjected to an electrolytic plating treatment in a copper sulfate bath at a current density of 3.0 A/dm² for 5 minutes to form an outermost layer, which is a metal plating layer, on the second layer. After that, the laminate was subjected to washing with water and an anticorrosive treatment, and excess moisture in the laminate was removed with air to obtain a laminate in which three metal layers were formed on the edge face.

<<Separation Step>>

Next, the laminate in which three metal layers had been formed on the edge face was separated for each functional layer laminate 11 by shearing through application of an external force in a direction horizontal to the surface of the functional layer laminate 11, whereby a laminated film 10b having the three-layer structure edge face sealing layer 16b of the first underlayer 18a made of titanium, the second underlayer 18b made of copper, and the shielding layer 20 made of copper was formed on the edge face of the functional layer laminate 11 was obtained.

Ten laminated films 10b were arbitrarily selected, each laminated film 10b was cut along an arbitrary cutting line, the microtome cutting was carried out to prepare the cut surface, and the thickness of the edge face sealing layer 16b exposed to the cut surface was measured using an optical microscope. As a result, the thickness of the edge face sealing layer 16b was 3 μm at any measurement point.

### Examples 2 and 3

A laminated film 10b was produced in the same manner as in Example 1, except that the time of electrolytic plating treatment for forming the shielding layer 20 was changed.

The thickness of the edge face sealing layer 16b was measured in the same manner as in Example 1 and it was 5 μm (Example 2) and 1 μm (Example 3).

### Example 4

A laminated film 10b was produced in the same manner as in Example 1, except that in the production of the functional layer laminate 11, the surface roughness Ra of the edge face was adjusted using an edge face treatment apparatus MCPL-300 manufactured by Megaro Technica Co., Ltd., instead of RETORATOME REM-710 manufactured by Yamato Kohki Industrial Co., Ltd.).

The surface roughness Ra of the edge face of the laminate, that is, the functional layer laminate 11 was measured in the same manner as in Example 1, and the surface roughness Ra of the edge face was 0.1 μm.

### Examples 5 and 6

A laminated film 10b was produced in the same manner as in Example 4, except that the time of electrolytic plating treatment for forming the shielding layer 20 was changed.

The thickness of the edge face sealing layer 16b was measured in the same manner as in Example 1 and it was 5 μm (Example 5) and 1 μm (Example 6).

### Example 7

A laminated film 10b was produced in the same manner as in Example 1, except that, in the production of the functional layer laminate 11, the conditions for adjusting the surface roughness Ra of the edge face were changed from the blade angle of 0° and the cutting amount of 10 μm to the blade angle of 0° and the cutting amount of 20 μm.

The surface roughness Ra of the edge face of the laminate, that is, the functional layer laminate 11 was measured in the same manner as in Example 1, and the surface roughness Ra of the edge face was 1.7 μm.

### Examples 8 and 9

A laminated film 10b was produced in the same manner as in Example 7, except that the time of electrolytic plating treatment for forming the shielding layer 20 was changed.

The thickness of the edge face sealing layer 16b was measured in the same manner as in Example 1 and it was 5 μm (Example 8) and 1 μm (Example 9).

### Example 10

A laminated film 10a as shown in FIG. 1 was produced in the same manner as in Example 1, except that the edge face sealing layer was a two-layer structure edge face sealing layer 16a having an underlayer 18 made of an organic layer and a shielding layer 20 made of an inorganic layer, instead of the three-layer structure edge face sealing layer 16b having a first underlayer 18a made of titanium, a second underlayer made of copper, and a shielding layer 20 made of copper.

The formation of the underlayer 18 and the shielding layer 20 is as follows.

<Formation of Underlayer 18 (Organic Layer)>

A composition having a solid content of the following composition was prepared. The composition is a part by mass in the case where the solid content as a whole is 100 parts by mass.

| | | |
|---|---|---|
| Base compound of two-component curing type | 66.7 | parts by mass |
| epoxy compound (polymerizable compound, | | |
| hydrophilicity logP = 3.8, base | | |
| compound of Loctite E-30CL, | | |
| manufactured by Henkel Japan Ltd.) | | |
| Curing agent for two-component curing type | 33.3 | parts by mass |
| epoxy compound (curing agent for LOCTITE | | |
| E-30CL, manufactured by Henkel Japan Ltd.) | | |

This composition was applied onto the entire edge face of the laminate and dried and cured at 80° C. for 10 minutes to form the underlayer 18.

The thickness of the underlayer 18 was 0.95 μm.

<Formation of Shielding Layer 20 (Inorganic Layer)>

An inorganic layer (silicon nitride (SiN) layer) was formed as the shielding layer 20 on the underlayer 18 by using a batch type plasma CVD apparatus.

For the formation of the inorganic layer, silane gas (flow rate of 160 sccm), ammonia gas (flow rate of 370 sccm), hydrogen gas (flow rate of 590 sccm), and nitrogen gas (flow rate of 240 sccm) were used as raw material gases. As the power source, a high frequency power source with a frequency of 13.56 MHz was used. The film forming pressure was set to 40 Pa.

The thickness of the formed shielding layer 20 was 50 nm.

The thickness of the edge face sealing layer 16b was measured in the same manner as in Example 1, and the thickness of the edge face sealing layer 16a was 1 μm.

### Examples 11 and 12

A laminated film 10a was produced in the same manner as in Example 10, except that the film thickness of the coating film for forming the underlayer 18 was changed.

The thickness of the edge face sealing layer 16b was measured in the same manner as in Example 1 and it was 2 μm (Example 11) and 5 μm (Example 12).

### Example 13

A laminated film 10a was produced in the same manner as in Example 10, except that, in the production of the functional layer laminate 11, the surface roughness Ra of the edge face was adjusted in the same manner as in Example 4.

### Examples 14 and 15

A laminated film 10a was produced in the same manner as in Example 13, except that the film thickness of the coating film for forming the underlayer 18 was changed.

The thickness of the edge face sealing layer 16b was measured in the same manner as in Example 1 and it was 2 μm (Example 14) and 5 μm (Example 15).

### Example 16

A laminated film 10a was produced in the same manner as in Example 10, except that, in the production of the functional layer laminate 11, the surface roughness Ra of the edge face was adjusted in the same manner as in Example 7.

### Examples 17 and 18

A laminated film 10a was produced in the same manner as in Example 16, except that the film thickness of the coating film for forming the underlayer 18 was changed.

The thickness of the edge face sealing layer 16b was measured in the same manner as in Example 1 and it was 2 μm (Example 17) and 5 μm (Example 18).

### Comparative Examples 1 and 2

A laminated film was produced in the same manner as in Example 1, except that the time of electrolytic plating treatment for forming the shielding layer 20 was changed.

The thickness of the edge face sealing layer 16b was measured in the same manner as in Example 1 and it was 0.2 μm (Comparative Example 1) and 10 μm (Comparative Example 2).

### Comparative Examples 3 and 4

A laminated film was produced in the same manner as in Example 4, except that the time of electrolytic plating treatment for forming the shielding layer 20 was changed.

The thickness of the edge face sealing layer 16b was measured in the same manner as in Example 1 and it was 0.2 μm (Comparative Example 3) and 10 μm (Comparative Example 4).

### Comparative Examples 5 and 6

A laminated film was produced in the same manner as in Example 7, except that the time of electrolytic plating treatment for forming the shielding layer 20 was changed.

The thickness of the edge face sealing layer 16b was measured in the same manner as in Example 1 and it was 0.2 μm (Comparative Example 5) and 10 μm (Comparative Example 6).

### Comparative Example 7

A laminated film was produced in the same manner as in Example 1, except that, in sheet processing for cutting a laminate having the gas barrier layers 14 laminated on both surfaces of the optical functional layer 12 to A4 size, laser cutting was used instead of punching with a Thomson blade; and in the production of the functional layer laminate 11, the surface roughness Ra of the edge face was not adjusted.

The surface roughness Ra of the edge face of the laminate, that is, the functional layer laminate 11 was measured in the same manner as in Example 1, and the surface roughness Ra of the edge face was 0.05 μm.

### Comparative Example 8

A laminated film was produced in the same manner as in Example 1, except that, in sheet processing for cutting a laminate having the gas barrier layers 14 laminated on both surfaces of the optical functional layer 12 to A4 size, a cutting plotter (FC-4200, manufactured by Graphtec Corporation) was used instead of punching with a Thomson blade; and in the production of the functional layer laminate 11, the surface roughness Ra of the edge face was not adjusted.

The surface roughness Ra of the edge face of the laminate, that is, the functional layer laminate 11 was measured in the same manner as in Example 1, and the surface roughness Ra of the edge face exceeded 10 μm.

### Comparative Example 9

A laminated film was produced in the same manner as in Example 4, except that the edge face sealing layer was formed only of the organic layer formed in the same manner as in the formation of the underlayer (organic layer) in Example 10.

The thickness of the edge face sealing layer was measured in the same manner as in Example 1 and it was 20 μm.

### Comparative Example 10

A laminated film was produced in the same manner as in Comparative Example 9, except that, in the production of the functional layer laminate 11, the surface roughness Ra of the edge face was adjusted in the same manner as in Example 1.

### Comparative Example 11

A laminated film was produced in the same manner as in Comparative Example 9, except that the sheet processing was carried out in the same manner as in Comparative Example 8 and the surface roughness Ra of the edge face of the laminate was not adjusted in the production of the functional layer laminate 11.

### Comparative Example 12

A laminated film was produced in the same manner as in Example 4, except that the edge face sealing layer was formed only of the inorganic layer formed in the same manner as in the formation of the shielding layer 20 (inorganic layer (silicon nitride layer)) in Example 10.

### Comparative Example 13

A laminated film was produced in the same manner as in Comparative Example 12, except that, in the production of the functional layer laminate 11, the surface roughness Ra of the edge face was adjusted in the same manner as in Example 1.

### Comparative Example 14

A laminated film was produced in the same manner as in Comparative Example 12, except that the sheet processing was carried out in the same manner as in Comparative Example 8 and the surface roughness Ra of the edge face was not adjusted in the production of the functional layer laminate 11.

### Comparative Example 15

A laminated film was produced in the same manner as in Example 10, except that the sheet processing was carried out in the same manner as in Comparative Example 8 and the surface roughness Ra of the edge face was not adjusted in the production of the functional layer laminate 11.

### Comparative Example 16

A laminated film was produced in the same manner as in Example 11, except that the sheet processing was carried out in the same manner as in Comparative Example 8 and the surface roughness Ra of the edge face was not adjusted in the production of the functional layer laminate 11.

### Comparative Example 17

A laminated film was produced in the same manner as in Example 12, except that the sheet processing was carried out in the same manner as in Comparative Example 8 and the surface roughness Ra of the edge face was not adjusted in the production of the functional layer laminate 11.

### Reference Example

A laminated film was produced in the same manner as in Example 1, except that the edge face sealing layer was formed only of the organic layer formed in the same manner as in the formation of the underlayer (organic layer) in Example 10.

The thickness of the edge face sealing layer was measured in the same manner as in Example 1 and it was 60 μm.

[Evaluation]

For the laminated films thus produced, edge face sealing performance and adhesiveness of the edge face sealing layer were evaluated.

<Evaluation of Edge Face Sealing Performance>

The initial luminance (Y0) of the laminated film was measured by the following procedure.

A backlight unit was taken out by disassembling a commercially available tablet terminal (Kindle (registered trademark) Fire HDX 7, manufactured by Amazon). The laminated film was placed on the light guide plate of the backlight unit taken out, and two prism sheets whose orientations were orthogonal to each other were laid thereon. The luminance of the light emitted from a blue light source and transmitted through the laminated film and the two prism sheets was measured by a luminance meter (SR3, manufactured by Topcon Corporation) set at a position 740 mm apart in the direction perpendicular to the plane of the light guide plate, and the obtained value was taken as luminance of the laminated film.

Next, the laminated film was placed in a constant-temperature tank kept at a temperature of 60° C. and a relative humidity of 90%, and stored for 1,000 hours. After 1,000 hours, the laminated film was taken out and the luminance (Y1) after the high-temperature high-humidity test was measured in the same procedure as above.

The change rate (ΔY) of the luminance (Y1) after the high-temperature high-humidity test relative to the initial luminance value (Y0) was calculated according to the following expression and evaluated as the index of luminance change according to the following standards.

ΔY[%]=(Y0−Y1)/Y0×100

In the case where the evaluation result was C or more, it can be determined that the luminance efficiency at the edge portion was maintained satisfactorily even after the high-temperature high-humidity test.

A: ΔY≤5%

B: 5%<ΔY<10%

C: 10%≤ΔY<15%

D: 15%≤ΔY

<Evaluation of Adhesiveness (Rubbing Test)>

The upper surface of the edge sealing layer of the laminate of 1,000 functional layer laminates 11 before being subjected to the separation step was fixed to the head of a rubbing tester through an eraser (MONO, manufactured by Tombow Pencil Co., Ltd.) cut into a bottom surface of 20 mm×20 mm×10 mm in height, and was vertically pressed from above with a load of 100 g/cm².

Under conditions of a temperature of 25° C. and a relative humidity of 60 RH %, 200 reciprocations were made at a stroke length of 3.5 cm and a rubbing speed of 1.8 cm/s. The rubbing was carried out in a direction parallel to the main surface of the functional layer laminate. After completion of the rubbing test, the extent of breakage of the edge sealing layer of the entire rubbed area was observed with a microscope. The extent of adhesiveness was evaluated in the following six levels, based on the size and frequency of scratches due to rubbing. Evaluation A and B can be said to have sufficient adhesiveness.

A: Neither damage nor peeling can be confirmed in the edge sealing layer even in the case of being very carefully observed.

B: Damage can be confirmed slightly on the surface of the edge sealing layer in the case of being very carefully observed, and the number of places where damage can be confirmed is within 5 among the rubbed regions.

C: It satisfies at least one of that there is apparent damage on the surface of the edge sealing layer and damage can be confirmed slightly on the surface of the edge sealing layer in the case of being very carefully observed, or that there are 6 or more places where damage can be confirmed, among the rubbed regions.

D: There is a portion where the edge sealing layer is peeled off and the edge face of the functional layer laminate is exposed.

E: The edge face of the functional layer laminate is exposed in the entire rubbed region

The results are shown in the following table.

TABLE 1

| | Surface | | | | |
|---|---|---|---|---|---|
| | roughness | Edge sealing layer | | Evaluation | |
| | of laminate | | Thick- | Sealing | Adhe- |
| | edge face | | ness | perfor- | sive- |
| | [μm] | Configuration | [μm] | mance | ness |
| Example 1 | 0.6 | Ti sputtering/ | 3 | A | A |
| | | Cu sputtering/ | | | |
| | | Cu plating | | | |
| Example 2 | 0.6 | Ti sputtering/ | 5 | A | A |
| | | Cu sputtering/ | | | |
| | | Cu plating | | | |
| Example 3 | 0.6 | Ti sputtering/ | 1 | A | A |
| | | Cu sputtering/ | | | |
| | | Cu plating | | | |
| Example 4 | 0.1 | Ti sputtering/ | 3 | A | A |
| | | Cu sputtering/ | | | |
| | | Cu plating | | | |
| Example 5 | 0.1 | Ti sputtering/ | 5 | A | B |
| | | Ci sputtering/ | | | |
| | | Cu plating | | | |
| Example 6 | 0.1 | Ti sputtering/ | 1 | A | B |
| | | Cu sputtering/ | | | |
| | | Cu plating | | | |
| Example 7 | 1.7 | Ti sputtering/ | 3 | B | A |
| | | Cu sputtering/ | | | |
| | | Cu plating | | | |
| Example 8 | 1.7 | Ti sputtering/ | 5 | B | B |
| | | Cu sputtering/ | | | |
| | | Cu plating | | | |
| Example 9 | 1.7 | Ti sputtering/ | 1 | B | A |
| | | Cu sputtering/ | | | |
| | | Cu plating | | | |
| Example 10 | 0.6 | Organic layer/ | 1 | B | A |
| | | SiN-CVD | | | |
| Example 11 | 0.6 | Organic layer/ | 2 | B | A |
| | | SiN-CVD | | | |
| Example 12 | 0.6 | Organic layer/ | 5 | C | A |
| | | SiN-CVD | | | |
| Example 13 | 0.1 | Organic layer/ | 1 | B | A |
| | | SiN-CVD | | | |
| Example 14 | 0.1 | Organic layer/ | 2 | B | B |
| | | SiN-CVD | | | |
| Example 15 | 0.1 | Organic layer/ | 5 | B | B |
| | | SiN-CVD | | | |
| Example 16 | 1.7 | Organic layer/ | 1 | C | A |
| | | SiN-CVD | | | |
| Example 17 | 1.7 | Organic layer/ | 2 | C | A |
| | | SiN-CVD | | | |
| Example 18 | 1.7 | Organic layer/ | 5 | C | A |
| | | SiN-CVD | | | |
| Comparative | 0.6 | Ti sputteriug/ | 0.2 | D | *1 |
| Example 1 | | Cu sputtering/ | | | |
| | | Cu plating | | | |
| Comparative | 0.6 | Ti sputtering/ | 10 | C | C |
| Example 2 | | Cu sputtering/ | | | |
| | | Cuplating | | | |
| Comparative | 0.1 | Ti sputtering/ | 0.2 | D | B |
| Example 3 | | Cu sputtering/ | | | |
| | | Cu plating | | | |
| Comparative | 0.1 | Ti sputtering/ | 10 | C | C |
| Example 4 | | Cu sputtering/ | | | |
| | | Cu plating | | | |
| Comparative | 1.7 | Ti sputtering/ | 0.2 | D | *1 |
| Example 5 | | Cu sputtering/ | | | |
| | | Cu plating | | | |
| Comparative | 1.7 | Ti sputtering/ | 10 | C | C |
| Example 6 | | Cu sputtering/ | | | |
| | | Cu plating | | | |
| Comparative | 0.05 | Ti sputtering/ | 3 | A | B |
| Example 7 | | Cu sputtering/ | | | |
| | | Cu plating | | | |
| Comparative | >10 | Ti sputtering/ | 3 | D | *1 |
| Example 8 | | Cu sputtering/ | | | |
| | | Cu plating | | | |
| Comparative | 0.1 | Epoxy resin | 20 | D | B |
| Example 9 | | sealed | | | |
| Comparative | 0.6 | Epoxy resin | 20 | D | A |
| Example 10 | | sealed | | | |
| Comparative | >10 | Epoxy resin | 20 | D | A |
| Example 11 | | sealed | | | |
| Comparative | 0.1 | SiN-CVD | 0.005 | D | *2 |
| Example 12 | | | | | |
| Comparative | 0.6 | SiN-CVD | 0.005 | D | *2 |
| Example 13 | | | | | |
| Comparative | >10 | SiN-CVD | 0.005 | D | *2 |
| Example 14 | | | | | |
| Comparative | >10 | Organic layer/ | 1 | D | A |
| Example 15 | | SiN-CVD | | | |
| Comparative | >10 | Organic layer/ | 2 | D | A |
| Example 16 | | SiN-CVD | | | |
| Comparative | >10 | Organic layer/ | 5 | D | A |
| Example 17 | | SiN-CVD | | | |
| Reference | 0.6 | Epoxy resin | 60 | A | A |
| Example | | sealed | | | |

In “*1” in the above table, the adhesiveness was not evaluated since the exposure of the edge face of the functional layer laminate was confirmed by microscopic observation in a state before the rubbing test was carried out.
In “*2”, the adhesiveness was not evaluated since the presence or absence of a silicon nitride layer cannot be observed.

As shown in Table 1 above, the laminated film of the present invention is capable of realizing an edge face sealing structure in which the edge face sealing layer is in a very narrow range relative to the laminated films of the Comparative Examples, oxygen and water are sufficiently blocked to suppress deterioration of quantum dots, and the edge face sealing layer is not damaged or detached even under severe handling conditions.

From the above results, the effects of the present invention are obvious.

The laminated film of the present invention can be suitably used for a variety of optical applications such as LCDs.

### EXPLANATION OF REFERENCES

10a, 10b, 10c: laminated film
11: functional layer laminate
12: optical functional layer
14: gas barrier layer (gas barrier film)
16a, 16b, 16c: edge face sealing layer
18: underlayer
18a, 18A: first underlayer
18b: second underlayer
20, 20A: shielding layer
30: gas barrier support
32: barrier layer
34, 38: organic layer
36: inorganic layer
50: laminate
52: laminate on which underlayer is formed
54: laminate on which shielding layer is formed

What is claimed is:

1. A laminated film comprising:
a functional layer laminate having an optical functional layer and a gas barrier layer laminated on at least one main surface of the optical functional layer; and
an edge face scaling layer formed so as to cover at least a part of an edge face of the functional layer laminate,
wherein a surface roughness Ra of the edge face of the functional layer laminate in a formation region of the edge face sealing layer is 0.1 to 2 μm and a thickness of the edge face sealing layer is 1 to 5 μm.

2. The laminated film according to claim 1, wherein the edge face sealing layer is formed so as to cover the entire edge face of the functional layer laminate.

3. The laminated film according to claim 1, wherein the edge face sealing layer has at least one layer selected from the group consisting of a resin layer, a metal layer, a metal oxide layer, a metal nitride layer, a metal carbide layer, and a metal carbonitride layer.

4. The laminated film according to claim 1, wherein the edge face sealing layer has a laminated structure in which a plurality of layers are laminated.

5. The laminated film according to claim 4, wherein the edge face sealing layer has a plurality of metal layers.

6. The laminated film according to claim 5, wherein the edge face sealing layer has a metal plating layer and a metal layer provided between the metal plating layer and the edge face of the functional layer laminate.

7. The laminated film according to claim 6, wherein a plurality of metal layers are provided between the metal plating layer and the edge face of the functional layer laminate.

8. The laminated film according to claim 4, wherein the edge face sealing layer has at least one inorganic compound layer selected from the group consisting of a metal oxide layer, a metal nitride layer, a metal carbide layer, and a metal carbonitride layer, and a resin layer provided between the inorganic compound layer and the edge face of the functional layer laminate.
